(19) United States
(12) Patent Application Publication
(10) Pub. No.: US 2025/0118630 A1
(43) Pub. Date: Apr. 10, 2025

(54) DUAL SIDE STACKED TRANSISTOR

(71) Applicant: International Business Machines Corporation, Armonk, NY (US)

(72) Inventors: Ruilong Xie, Niskayuna, NY (US); Junli Wang, Slingerlands, NY (US); Kisik Choi, Watervliet, NY (US); Koichi Motoyama, Clifton Park, NY (US); Nicholas Anthony Lanzillo, Wynantskill, NY (US); Biswanath Senapati, Mechanicville, NY (US); Albert M. Chu, Nashua, NH (US); Brent A. Anderson, Jericho, VT (US); Chen Zhang, Santa Clara, CA (US); Tenko Yamashita, Schenectady, NY (US)

(21) Appl. No.: 18/377,672

(22) Filed: Oct. 6, 2023

(51) Int. Cl. H01L 23/48; H01L 21/8238; H01L 23/528; H01L 27/092; H01L 29/06; H01L 29/423; H01L 29/66; H01L 29/775; H01L 29/786

(52) U.S. Cl. CPC H01L 23/481; H01L 23/5283; H10D 30/014; H10D 30/43; H10D 30/6735; H10D 30/6757; H10D 62/121; H10D 64/017; H10D 84/017; H10D 84/0186; H10D 84/038; H10D 84/85

(57) ABSTRACT

A semiconductor structure includes an upper-level CMOS transistor layer having a plurality of upper-level N-type and P-type field effect transistors; and a frontside interconnect layer above, and interconnected with, the upper-level transistor layer. The frontside interconnect layer includes frontside power rails and frontside signal wiring, and at least three frontside interconnect layer metal levels. A lower-level CMOS transistor layer has a plurality of lower-level N-type and P-type field effect transistors; and a backside interconnect layer below, and interconnected with, the lower-level transistor layer. The backside interconnect layer includes backside power rails and backside signal wiring and at least three backside interconnect layer metal levels. At a peripheral region of the structure, at least one conductive interconnection is provided between a third or higher of the at least three frontside interconnect layer metal levels and a third or lower of the at least three backside interconnect layer metal levels.

### BACKGROUND

The present invention relates generally to the electrical, electronic and computer arts and, more particularly, to techniques for stacked CMOS FETs and the like.

Stacked FETs have been proposed to continue scaling integrated circuits to ever smaller technology nodes. FIG. 1 shows a first prior art approach wherein the cell height is maintained; this provides no performance benefit, and raises significant process challenges. Note the cell boundaries 301, N-type source-drain (S/D) region 303, P-type source-drain region 305, N-type source-drain region contact 307, and P-type source-drain region contact 309. The contact portions “CA” are formed from the front side and the contact portions “BSCA” are formed from the back side.

FIG. 2 shows a second prior art approach wherein the bottom device may be stronger, but at the cost of losing cell height. Note the cell boundaries 311, N-type source-drain region 313, P-type source-drain region 315, N-type source-drain region contact 317, and P-type source-drain region contact 319. The contact portions “CA” are formed from the front side and the contact portions “BSCA” are formed from the back side.

A pertinent issue with current stacked FET approaches is trying to locally wire the bottom device to the top, or the top device to the bottom. This either leads to poor performance (when trying to use extremely small contacts to save area for scaling and to reduce parasitic capacitance) or larger cell size (when trying to make a robust contact size, and contact spacing).

Furthermore, it is currently very challenging to produce stacked FETs with multiple threshold voltages (Vₜ) with monolithic flow. While bonded flow has helped with the goal of producing stacked FETs with multiple threshold voltages (Vₜ), bottom to top misalignment (even as small as 2˜3 nm) will destroy the process margin, because of the need to make fine contacts through from top to bottom, at very tight pitches (both gate pitch and metal layer (M1) pitch).

### BRIEF SUMMARY

Principles of the invention provide techniques for a dual side stacked transistor; for example, dual side stacked field effect transistor (FET) complementary oxide semiconductor (CMOS) structures for transistor scaling. In one aspect, an exemplary semiconductor structure includes an upper-level complementary metal oxide semiconductor (CMOS) transistor layer having a plurality of upper-level N-type field effect transistors and a plurality of upper-level P-type field effect transistors; a frontside interconnect layer above, and interconnected with, the upper-level complementary metal oxide semiconductor (CMOS) transistor layer, the frontside interconnect layer including both: (i) frontside power rails and (ii) frontside signal wiring, the frontside interconnect layer including at least three frontside interconnect layer metal levels; a lower-level complementary metal oxide semiconductor (CMOS) transistor layer having a plurality of lower-level N-type field effect transistors and a plurality of lower-level P-type field effect transistors; a backside interconnect layer below, and interconnected with, the lower-level complementary metal oxide semiconductor (CMOS) transistor layer, the backside interconnect layer including both: (i) backside power rails and (ii) backside signal wiring, the backside interconnect layer including at least three backside interconnect layer metal levels; and at least one conductive interconnection between a third or higher of the at least three frontside interconnect layer metal levels and a third or lower of the at least three backside interconnect layer metal levels, the at least one conductive interconnection being located at a peripheral region of the semiconductor structure.

Optionally, an intermediate dielectric region separates the upper-level complementary metal oxide semiconductor (CMOS) transistor layer and the lower-level complementary metal oxide semiconductor (CMOS) transistor layer.

Optionally, the frontside power rails and the frontside signal wiring are included in at least a first of the at least three frontside interconnect layer metal levels; and the backside power rails and the backside signal wiring are included in at least a first of the at least three backside interconnect layer metal levels.

Optionally, the at least one conductive interconnection is a deep via contact.

In another aspect, a hardware description language (HDL) design structure is encoded on a machine-readable data storage medium. The HDL design structure includes elements that when processed in a computer-aided design system generate a machine-executable representation of a semiconductor structure, as described.

In still a further aspect, an exemplary method of forming a semiconductor structure includes providing a starting structure including: a silicon substrate; an etch stop liner above the silicon substrate; an additional silicon substrate above the etch stop liner, the additional silicon substrate having a plurality of shallow trench isolation regions formed therein; bottom dielectric isolation (BDI) above the additional silicon substrate; and bottom dummy gate stacks above the bottom dielectric isolation (BDI), the bottom dummy gate stacks being separated by bottom source-drain regions and bottom gate cuts, the bottom dummy gate stacks surrounding bottom channel regions; bottom interlayer dielectric separating the bottom source-drain regions; and placeholders in the additional silicon substrate, inward of the bottom source-drain regions. Further steps include bonding, onto an outer surface of the starting structure, using a bonding layer, a top stack including alternating channel and sacrificial SiGe regions and an outer silicon substrate, to obtain a first intermediate structure; and processing the first intermediate structure to obtain a second intermediate structure including: the starting structure; the bonding layer; top high-K metal gate stacks above the bonding layer opposite the bottom dummy gate stacks, the top high-K metal gate stacks being separated by top source-drain regions and top gate cuts, the top high-K metal gate stacks surrounding top channel regions formed from the alternating channel regions of the top stack; top interlayer dielectric separating the top source-drain regions; top source, drain, and gate contacts; a frontside interconnect layer outward of the top high-K metal gate stacks, electrically interconnected with the top source, drain, and gate contacts and including both: (i) top power wiring and (ii) top signal wiring, the frontside interconnect layer including both: (i) frontside power rails and (ii) frontside signal wiring, the frontside interconnect layer including at least three frontside interconnect layer metal levels; a carrier wafer outward of the top wiring layer; and contacts at peripheral regions of the semiconductor structure and electrically interconnected to a third or higher of the at least three frontside interconnect layer metal levels and passing through the bonding layer, the bottom interlayer dielectric and the top interlayer dielectric. Further steps include flipping the second intermediate structure and etching the silicon substrate down to the etch stop liner; carrying out high-K metal gate replacement on the bottom dummy gate stacks; and forming bottom source, drain, and gate contacts, and a backside interconnect layer inward of the bottom replacement gates, electrically interconnected with the bottom source, drain, and gate contacts and including both bottom power and bottom signal wiring, the backside interconnect layer including both backside power rails and backside signal wiring, the backside interconnect layer including at least three backside interconnect layer metal levels, the contacts at the peripheral regions being electrically interconnected to a third or lower of the at least three backside interconnect layer metal levels, at least some of the placeholders being replaced by at least some of the bottom source, drain, and gate contacts.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Allow further scaling, enhanced yield, and/or enhanced reliability for semiconductor structures using stacked CMOS FETs; for example, scaling to the 2 nm technology node and beyond;
the lower device can be a device having a high thermal budget and can be completed early-on, overcoming the need to form any high thermal budget devices later;
top later devices can be formed with multiple threshold voltages;
reduce or eliminate need to form contacts to lower layer devices;
reduced criticality of RX (fin stack) overlay;
top layer can use known BEOL interconnects including both power distribution and signal lines;
bottom devices can be formed without need for high thermal budget annealing;
provision for backside interconnects including both power distribution and signal lines.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1 and 2 show stacked CMOS FET structures from the prior art;

FIG. 3 is a top view of a semiconductor structure, in accordance with an aspect of the invention (also generally representative of top views of intermediate structures during a formation process);

FIGS. 4A, 4B, and 4C are views of a starting structure in a semiconductor fabrication process, related to forming bottom CMOS transistors, taken along lines X, Y1, and Y2 respectively of FIG. 3, in accordance with an aspect of the invention;

FIGS. 5A, 5B, and 5C are views of the structure of FIGS. 4A-4C, after dummy gate removal, release of sacrificial SiGe, and high-K metal gate deposition, taken along lines X, Y1, and Y2 respectively of FIG. 3, in accordance with an aspect of the invention;

FIGS. 6A, 6B, and 6C are views of the structure of FIGS. 5A-5C, after thin TiN deposition, amorphous silicon (a-Si) deposition, reliability annealing, chemical-mechanical planarization (CMP), and gate cuts, taken along lines X, Y1, and Y2 respectively of FIG. 3, in accordance with an aspect of the invention;

FIGS. 7A, 7B, and 7C are views of the structure of FIGS. 6A-6C, after bonding on a top wafer, taken along lines X, Y1, and Y2 respectively of FIG. 3, in accordance with an aspect of the invention;

FIGS. 8A, 8B, and 8C are views of the structure of FIGS. 7A-7C, after removing the bonded-on Si-substrate, stopping on the bonded-on SiGe, taken along lines X, Y1, and Y2 respectively of FIG. 3, in accordance with an aspect of the invention;

FIGS. 9A, 9B, and 9C are views of the structure of FIGS. 8A-8C, after optional removal of the upmost bonded-on SiGe layer, taken along lines X, Y1, and Y2 respectively of FIG. 3, in accordance with an aspect of the invention;

FIGS. 10A, 10B, and 10C are views of the structure of FIGS. 9A-9C, after top RX (i.e., fin stack) patterning, dummy gate formation, spacer/inner spacer formation, S/D epitaxy (epi) formation, inter-layer dielectric (ILD) deposition and CMP, dummy gate removal, replacement high-K metal gate (HKMG) formation, and gate cut patterning, taken along lines X, Y1, and Y2 respectively of FIG. 3, in accordance with an aspect of the invention;

FIGS. 11A, 11B, and 11C are views of the structure of FIGS. 10A-10C, after forming middle of line (MOL) contacts, taken along lines X, Y1, and Y2 respectively of FIG. 3, in accordance with an aspect of the invention;

FIGS. 12A, 12B, and 12C are views of the structure of FIGS. 11A-11C, after forming back end of line (BEOL) wiring and bonding a carrier wafer, taken along lines X, Y1, and Y2 respectively of FIG. 3, in accordance with an aspect of the invention;

FIGS. 13A, 13B, and 13C are views of the structure of FIGS. 12A-12C, after wafer flipping and substrate removal, stopping on the SiGe, taken along lines X, Y1, and Y2 respectively of FIG. 3, in accordance with an aspect of the invention;

FIGS. 14A, 14B, and 14C are views of the structure of FIGS. 13A-13C, after SiGe removal and removal of epitaxially grown silicon, taken along lines X, Y1, and Y2 respectively of FIG. 3, in accordance with an aspect of the invention;

FIGS. 15A, 15B, and 15C are views of the structure of FIGS. 14A-14C, after back side gate spacer formation, taken along lines X, Y1, and Y2 respectively of FIG. 3, in accordance with an aspect of the invention;

FIGS. 16A, 16B, and 16C are views of the structure of FIGS. 14A-14C, after opening exposed HKMG material, taken along lines X, Y1, and Y2 respectively of FIG. 3, in accordance with an aspect of the invention;

FIGS. 17A, 17B, and 17C are views of the structure of FIGS. 16A-16C, after removal of a-Si and TiN for reliability, taken along lines X, Y1, and Y2 respectively of FIG. 3, in accordance with an aspect of the invention;

FIGS. 18A, 18B, and 18C are views of the structure of FIGS. 17A-17C, after forming replacement HKMG for the lower device, HKMG recess, and backside gate cap formation, taken along lines X, Y1, and Y2 respectively of FIG. 3, in accordance with an aspect of the invention;

FIGS. 19A, 19B, and 19C are views of the structure of FIGS. 18A-18C, after removing placeholders, backside gate contact patterning, and forming backside contacts, taken along lines X, Y1, and Y2 respectively of FIG. 3, in accordance with an aspect of the invention;

FIGS. 20A, 20B, and 20C are views of the structure of FIGS. 19A-19C, after forming backside interconnects, taken along lines X, Y1, and Y2 respectively of FIG. 3, in accordance with an aspect of the invention;

FIG. 21 depicts a computing environment according to an embodiment of the present invention (e.g., for implementing a design process such as that of FIG. 22);

FIG. 22 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

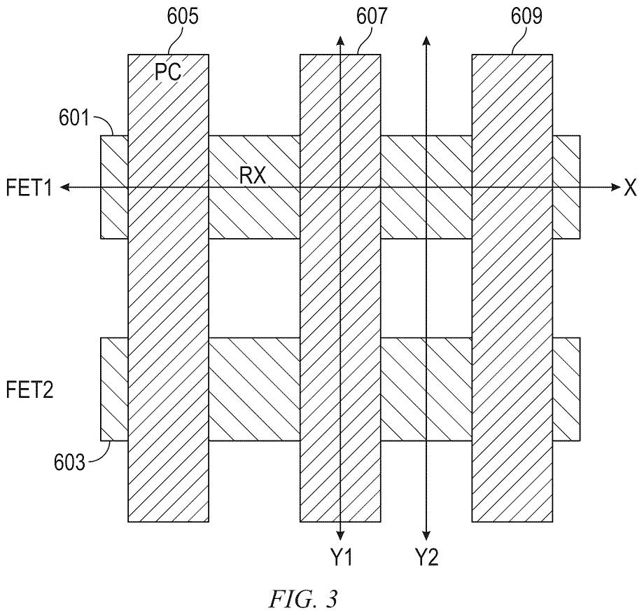

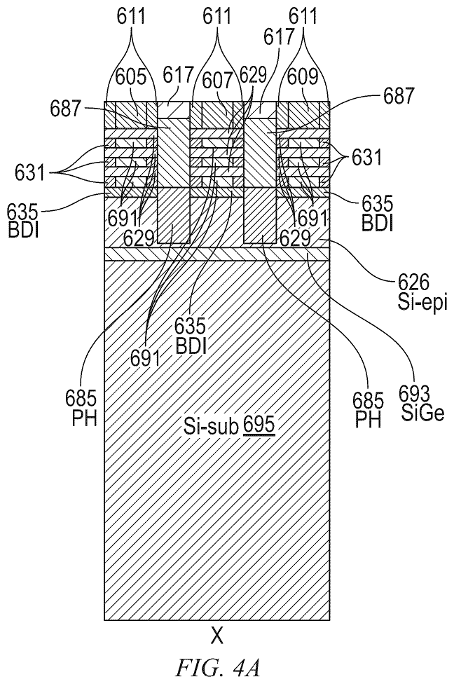

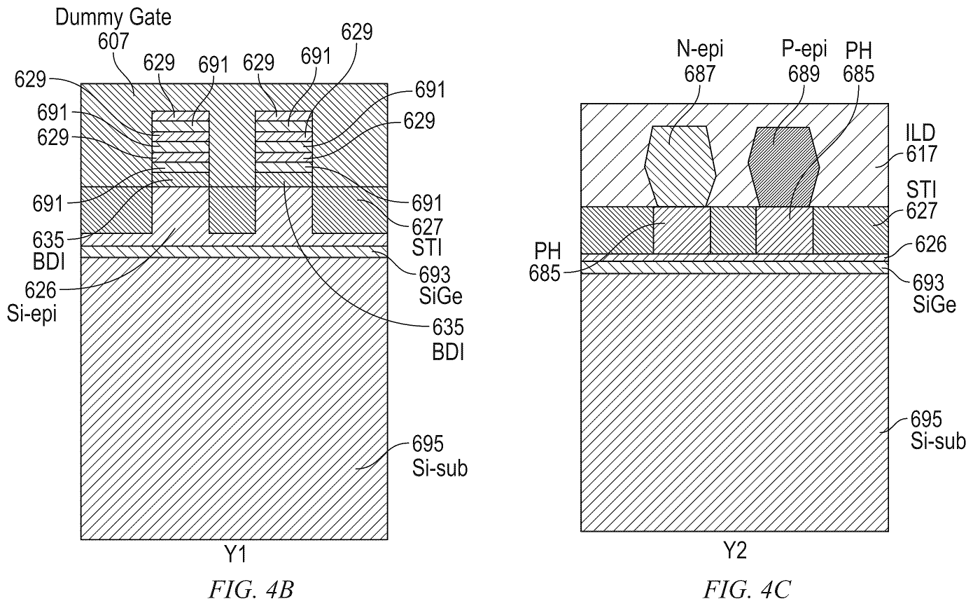

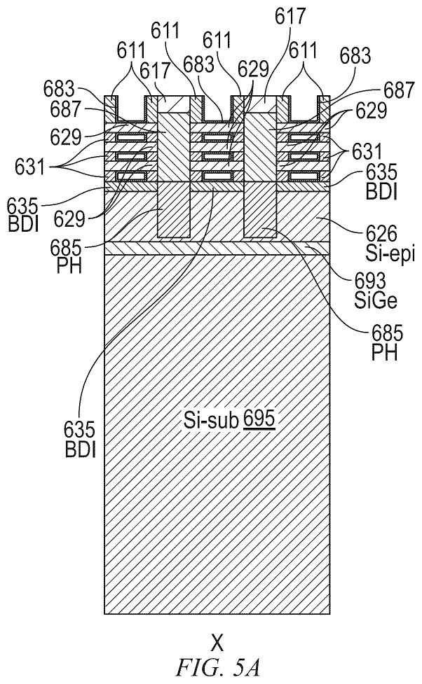

Aspects of invention provide techniques for dual side stacked field effect transistor (FET) complementary oxide semiconductor (CMOS) structures for transistor scaling; for example, scaling to the 2 nm technology node and beyond. Referring now to FIGS. 3 and 4A-4C, consider an exemplary process flow. FIG. 3 is a top view of aspects of an integrated circuit structure in accordance with an exemplary embodiment (generally representative of top views of the starting structure, intermediate structures, and final structure). The fin (stack of one or more nanosheets) 601 is for a first FET FET1 (generally, an NFET or PFET) and the fin (stack of one or more nanosheets) 603 is for a second FET FET2 (generally, a PFET or NFET). Note that, generally, the way the nanosheets are arranged can be, for example, NNPPNNPP, such that FET1 and FET2 can, in general, be N next to P, P next to N, P next to P, or N next to N; in the example depicted, FET1 is an NFET and FET2 is a PFET). Note the three dummy gates 605, 607, 609 (also representative of HKMG gates in the final structure). FIG. 4A is a cross-gate view of the device of FIG. 3 along line X in FIG. 3 while FIG. 4B is a cross-fin view of the device of FIG. 3 through gate 607 along line Y1 and FIG. 4C is a cross-fin view of the device of FIG. 3 between gates 607 and 609 (i.e., in the source/drain region region) along line Y2. The structure in FIGS. 3 and 4A-4C is a starting structure that can be made by the skilled artisan using known techniques given the teachings herein. Note dummy gates 605, 607, 609, gate spacers 611, nanosheet channels 629, inner spacers 631, remaining sacrificial SiGe 691, STI 627 (e.g., oxide), silicon substrate 695, etch stop layer (e.g., SiGe 693), additional silicon substrate 626 on top of the etch stop layer, bottom dielectric isolation (BDI) 635, interlayer dielectric (ILD) 617, p-type epitaxially grown S-D region 689, n-type epitaxially grown source-drain (S-D) region 687, and placeholders 685 (for backside contacts).

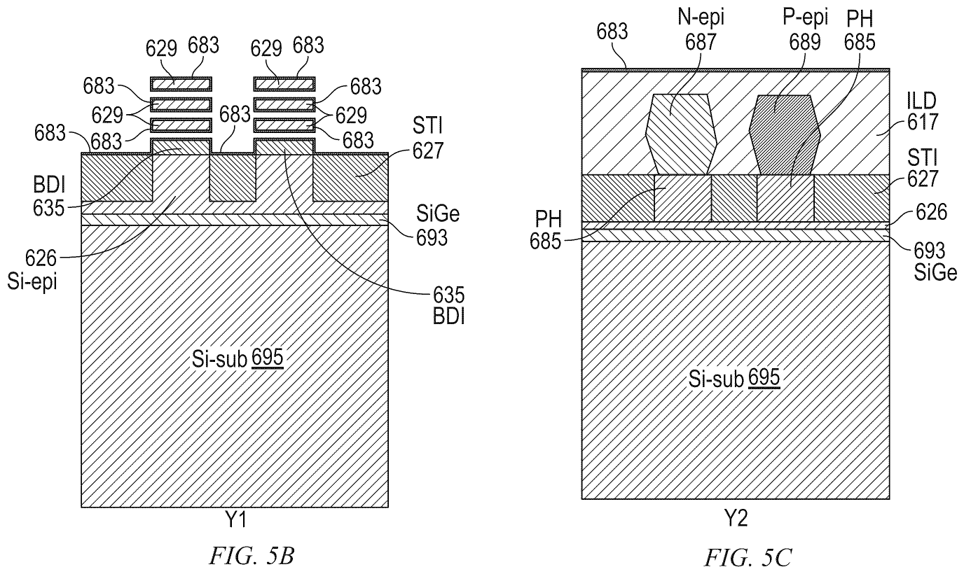

FIGS. 5A, 5B, and 5C are views of the structure of FIGS. 4A-4C, after dummy gate removal, release of sacrificial SiGe, and high-K gate dielectric deposition (i.e., deposition of hafnium oxide HfO₂ 683), taken along lines X, Y1, and Y2 respectively of FIG. 3.

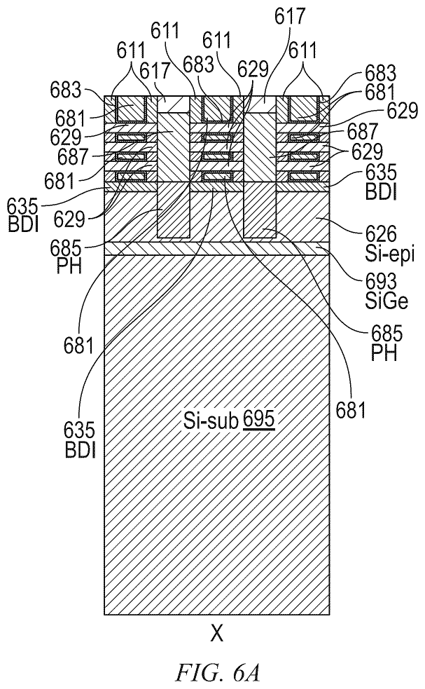

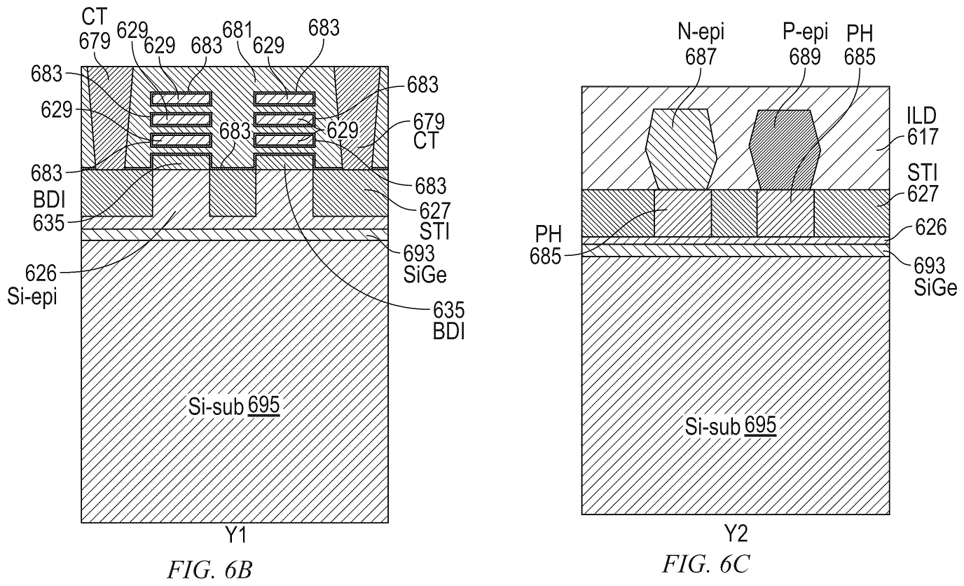

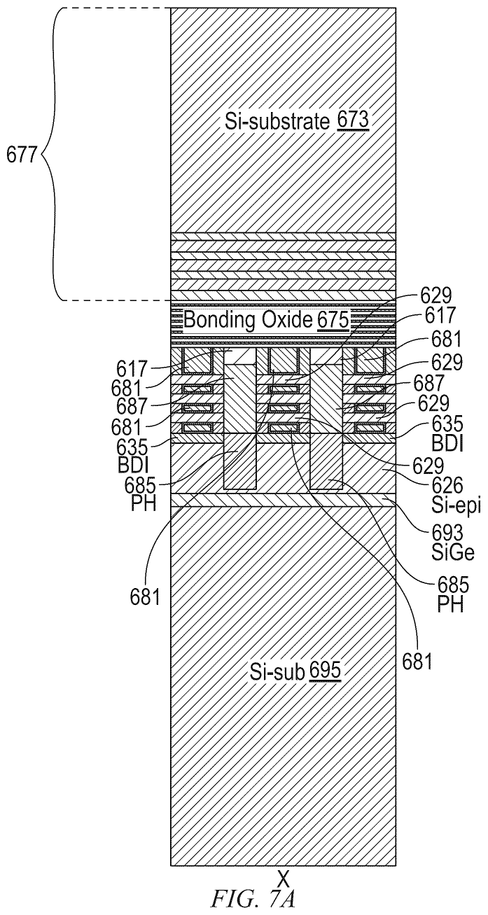

FIGS. 6A, 6B, and 6C are views of the structure of FIGS. 5A-5C, after deposition of thin TiN, deposition of amorphous silicon (a-Si), reliability annealing, chemical-mechanical planarization (CMP), and formation of gate cuts 679, taken along lines X, Y1, and Y2 respectively of FIG. 3. To avoid clutter, the thin TiN and a-Si are not shown separately; element 681 represents both TiN and a-Si. In a non-limiting example, the thickness of TiN is about 1.5 nm, and it can be deposited by atomic layer deposition (ALD) after which the indicated space is filled with a-Si followed by CMP.

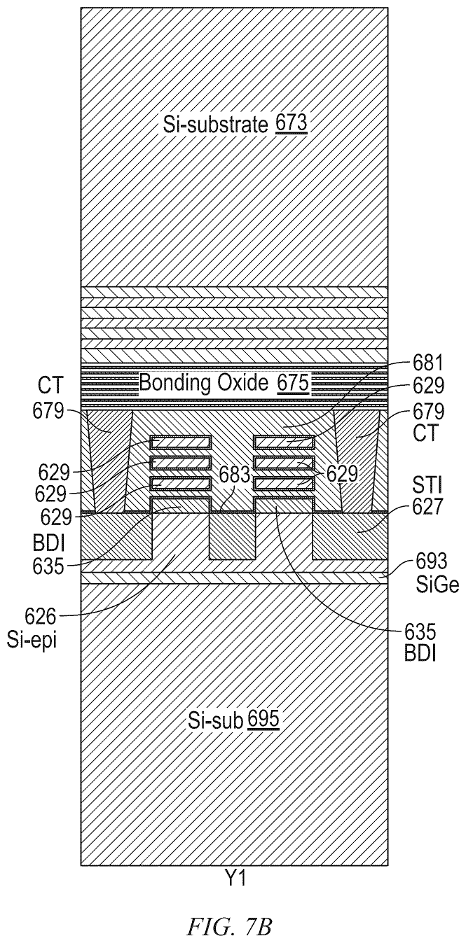

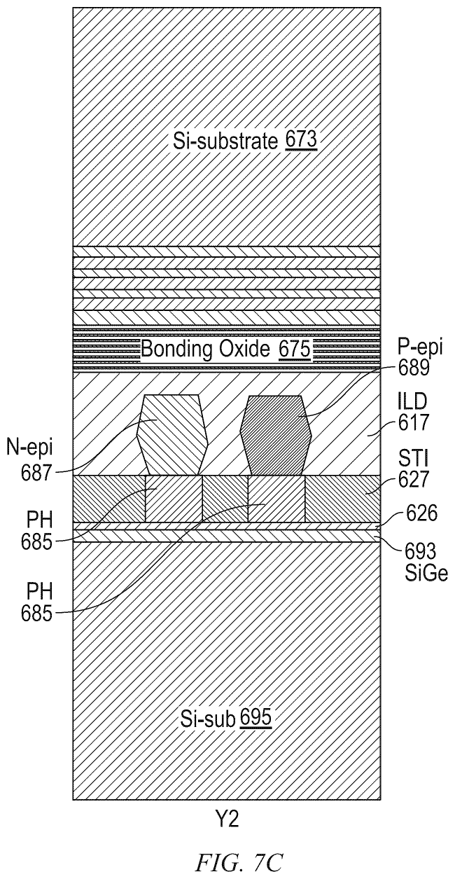

FIGS. 7A, 7B, and 7C are views of the structure of FIGS. 6A-6C, after bonding on a top stack 677 using bonding oxide 675, taken along lines X, Y1, and Y2 respectively of FIG. 3. The structure that is bonded on includes silicon substrate 673 with layers of alternating SiGe and Si, not separately numbered, adjacent the bonding oxide 675.

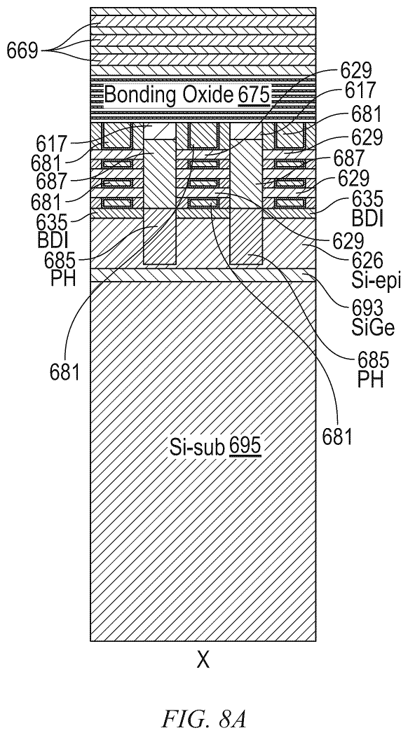

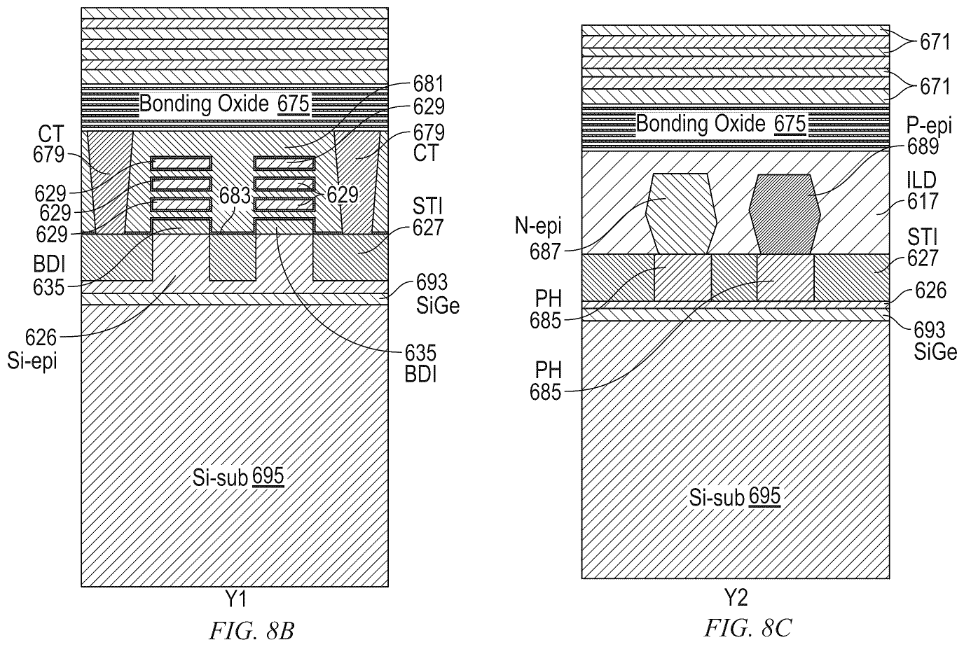

FIGS. 8A, 8B, and 8C are views of the structure of FIGS. 7A-7C, after removing the bonded-on Si-substrate, stopping on the bonded-on SiGe, taken along lines X, Y1, and Y2 respectively of FIG. 3. Here, the alternating SiGe and Si adjacent the bonding oxide 675 are numbered as 671 and 669, respectively.

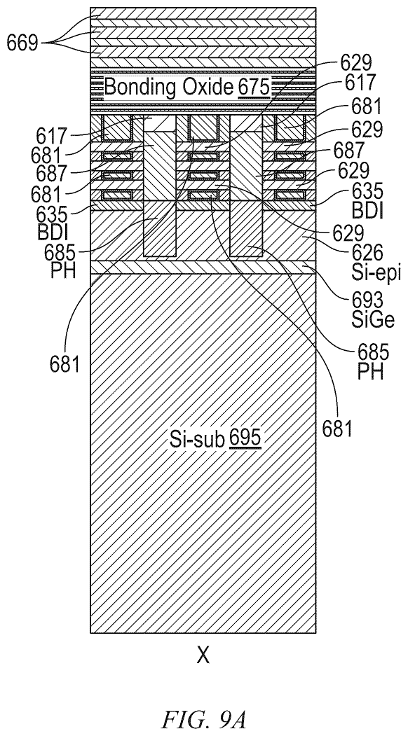

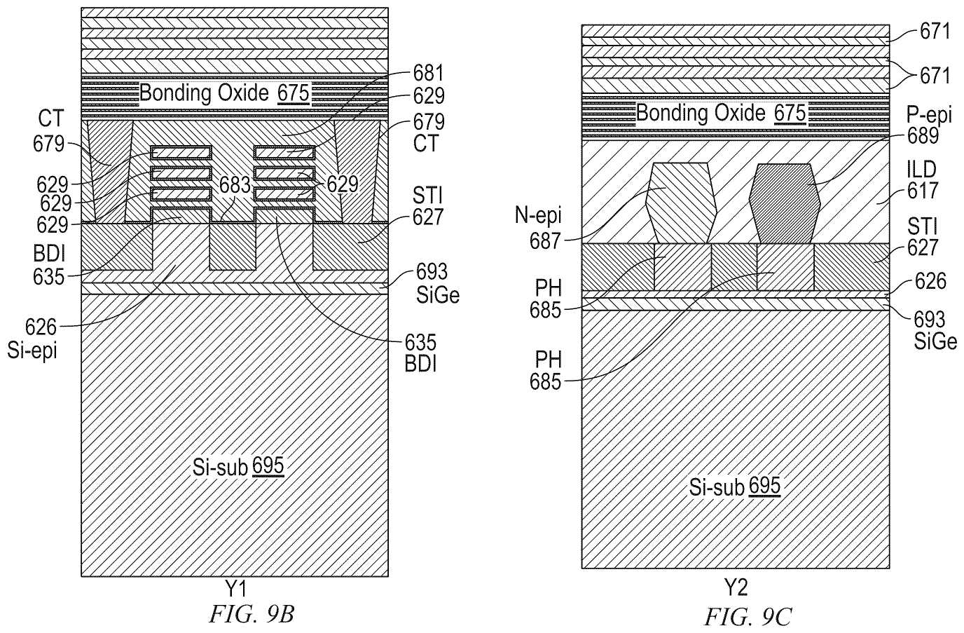

FIGS. 9A, 9B, and 9C are views of the structure of FIGS. 8A-8C, after optional removal of the upmost bonded-on SiGe layer 671, taken along lines X, Y1, and Y2 respectively of FIG. 3.

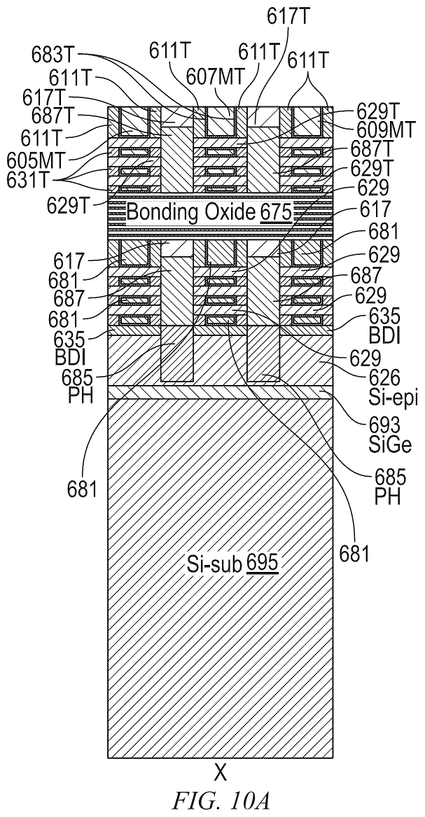

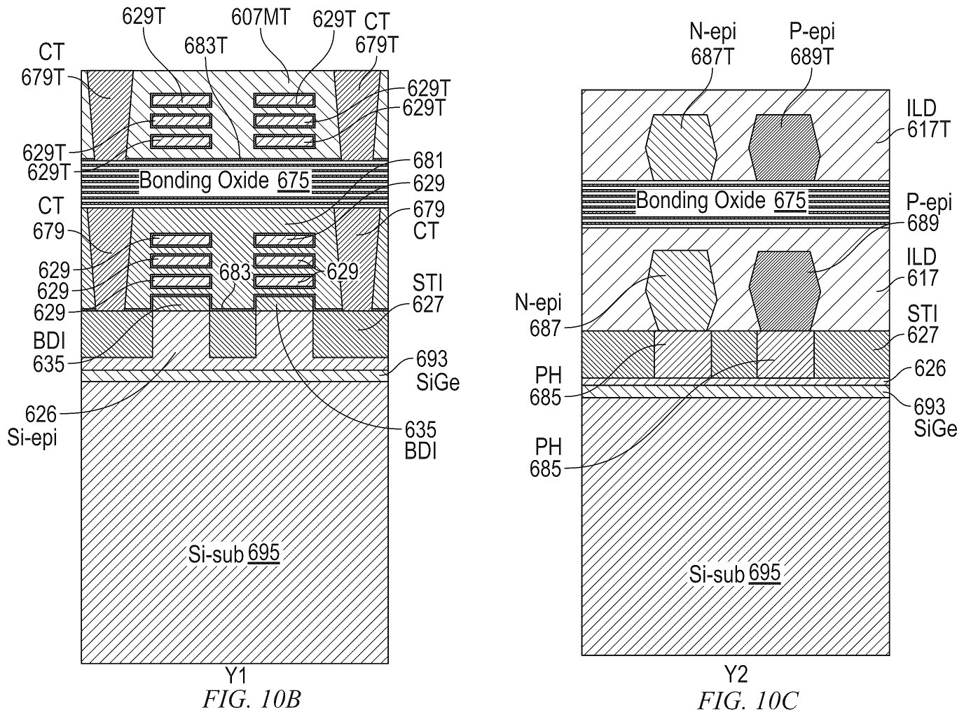

FIGS. 10A, 10B, and 10C are views of the structure of FIGS. 9A-9C, after top RX (fin stack) patterning, dummy gate formation, spacer/inner spacer formation, S/D epitaxy (epi) formation, inter-layer dielectric (ILD) deposition and CMP, dummy gate removal, replacement high-K metal gate (HKMG) formation, and gate cut patterning, taken along lines X, Y1, and Y2 respectively of FIG. 3. Given the teachings herein, the skilled person can use known techniques to carry out the indicated operations to obtain the structure depicted in FIGS. 10A-10C. Generally, items similar to those described for the lower layer are given the same reference character with a “T.” Note the top ILD 617T, top N-type epitaxially grown S-D region 687T, top P-type epitaxially grown S-D region 689T, top gate cuts 679T, top nanosheet channels 629T, top metal gate stacks—see metal portions 605MT, 607MT, 609 MT (note also top high-k gate dielectric 683T), top inner spacers 631T, and top gate spacers 611T.

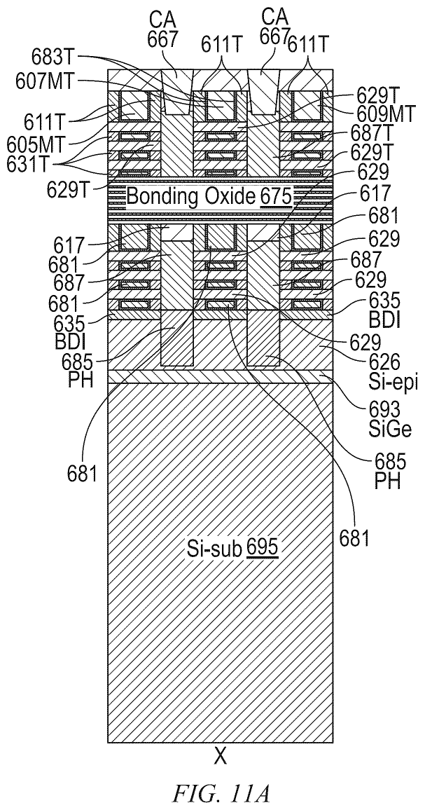

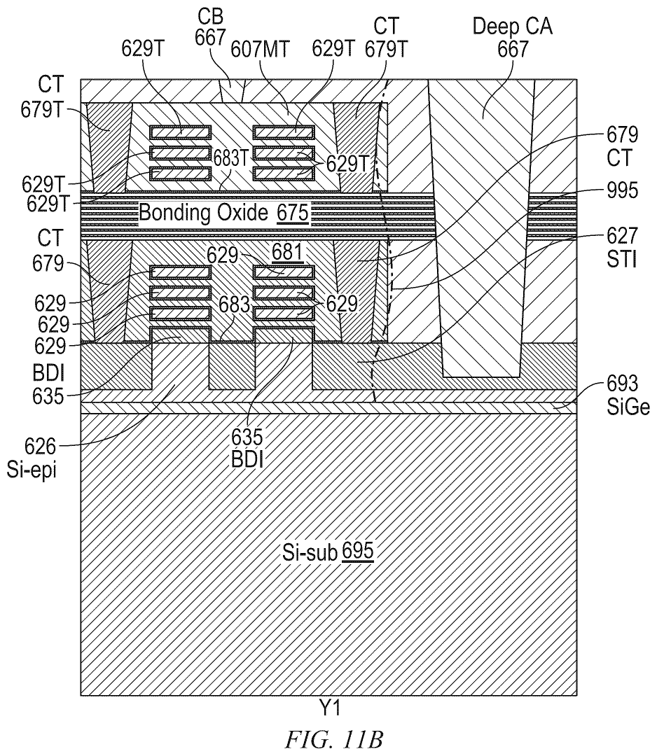

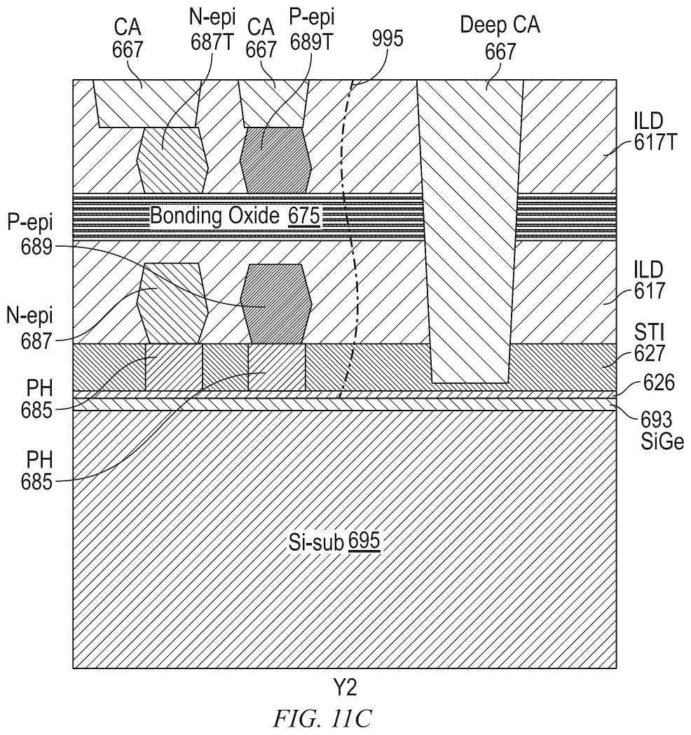

FIGS. 11A, 11B, and 11C are views of the structure of FIGS. 10A-10C, after depositing additional ILD 617T, and forming middle of line (MOL) contacts 667, taken along lines X, Y1, and Y2 respectively of FIG. 3. Note that the Y1 and Y2 views of FIGS. 11B and 11C also show peripheral regions where the deep via contact 667 is formed to extend from the MOL all the way down to the bottom of STI 627 (e.g., oxide), through the top ILD 617T, the bonding oxide 675, the bottom ILD 617, and the STI 627 (e.g., oxide).

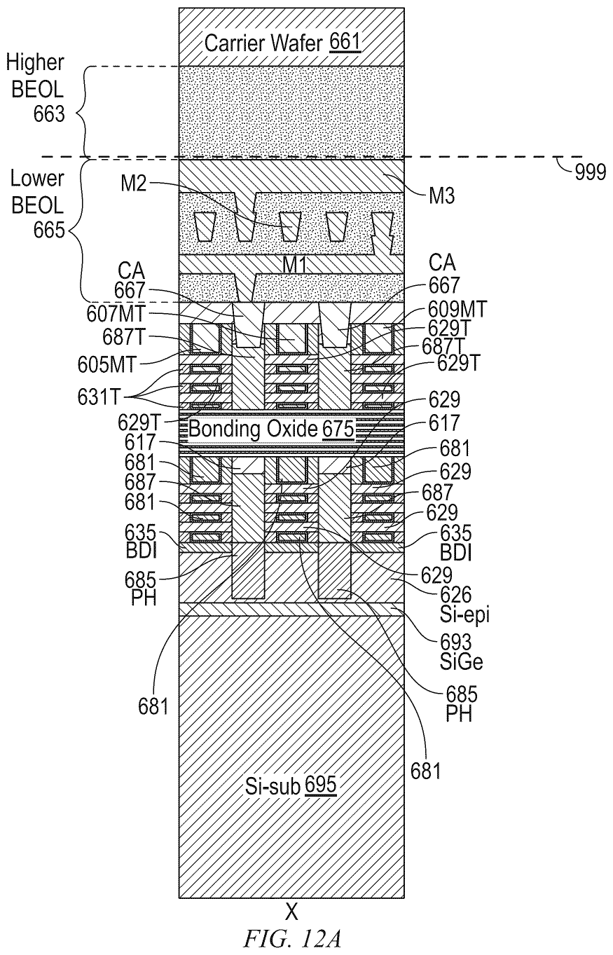

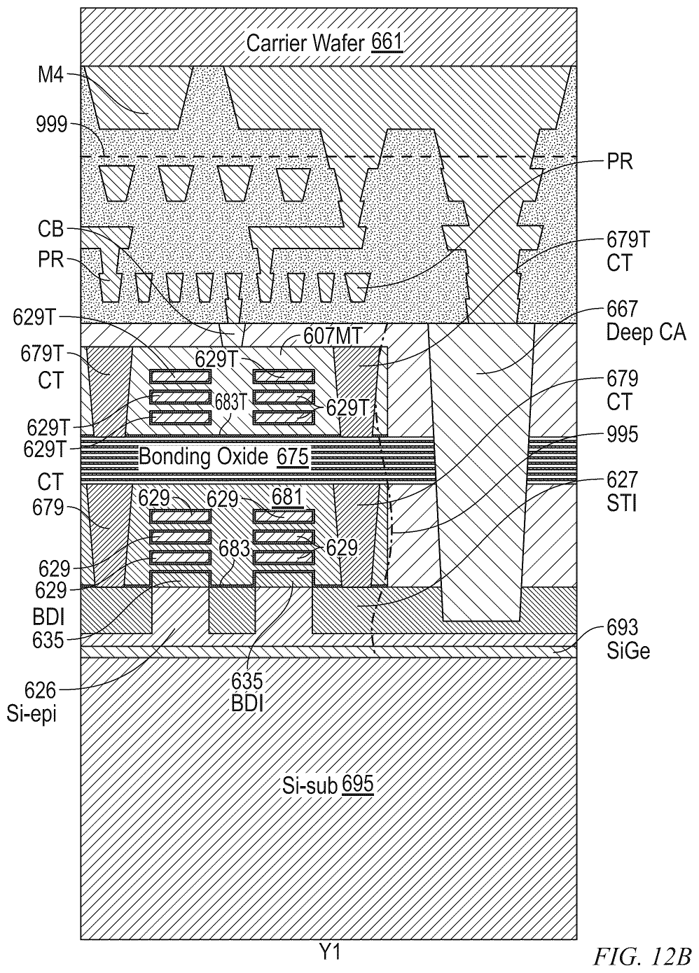

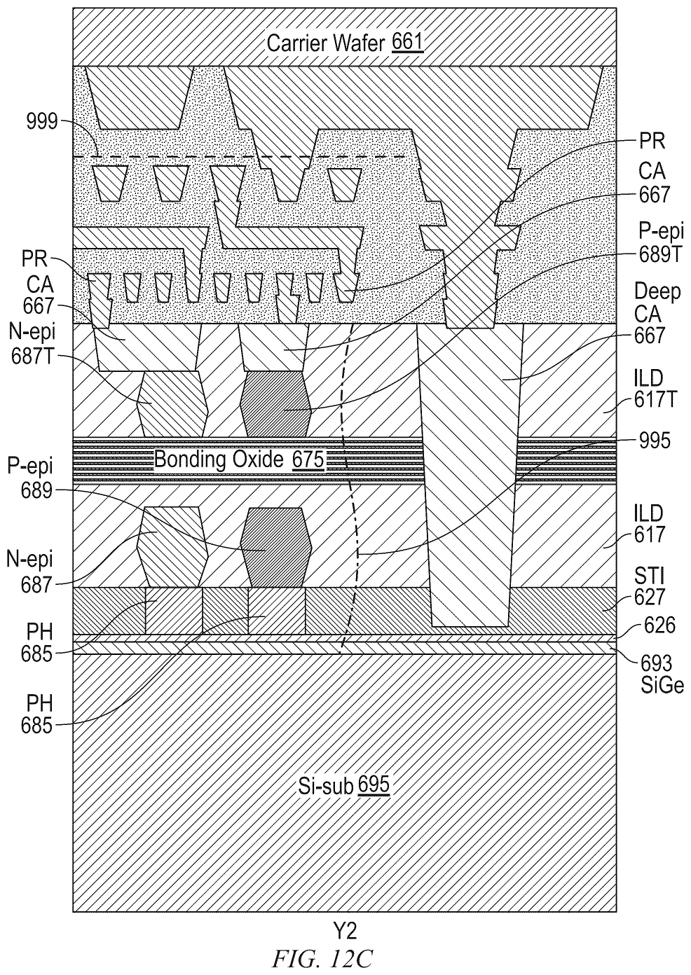

FIGS. 12A, 12B, and 12C are views of the structure of FIGS. 11A-11C, after forming back end of line (BEOL) wiring and bonding a carrier wafer, taken along lines X, Y1, and Y2 respectively of FIG. 3. Note the lower BEOL wiring 665, higher BEOL wiring 663, and carrier wafer 661. Both the lower BEOL wiring 665 and higher BEOL wiring 663 can contain additional layers of metal levels, and the drawing is for illustrative purposes and non-limiting. In the non-limiting example, there are four metal levels M1, M2, M3, M4 (M1, M2, and M3 are seen in FIG. 12A and M4 is seen in FIG. 12B). In the first metal level M1, there is wiring for both signal routing and power delivery (power rails (PRs)). Connections are established between the deep via contact 667 and the top CMOS terminals (n-epi S/D 687T, p-epi S/D 689T, and gates with gate metal portions 605MT, 607MT, 609MT) through higher BEOL wiring (in this context, higher BEOL wiring means: higher than M2, e.g., M3, M4, and so on). By way of clarification, as seen in FIGS. 12B and 12C, there are interconnections between contact 667 and M4, through M1, M2, and M3. The connections are established between the deep via contact 667 and the top CMOS terminals in M4 which extends laterally. Note that for illustrative convenience, metal layers are only draw up to M4; however, in the higher BEOL wiring 663, there can be more than four layers, and the connection to contact 667 can happen at a higher metal layer than M4. Given the teachings herein, the skilled artisan can form suitable BEOL wiring including metal layers with wires and vias and with suitable insulating material in between, by adapting known techniques.

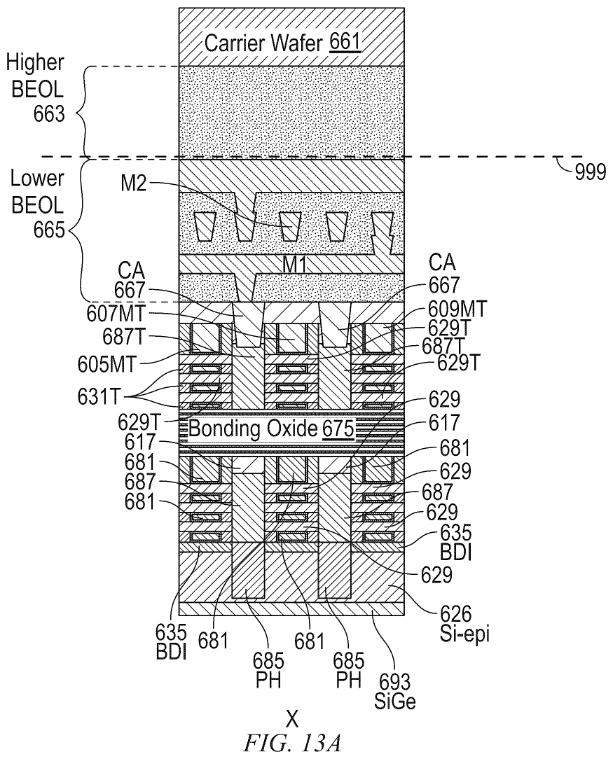

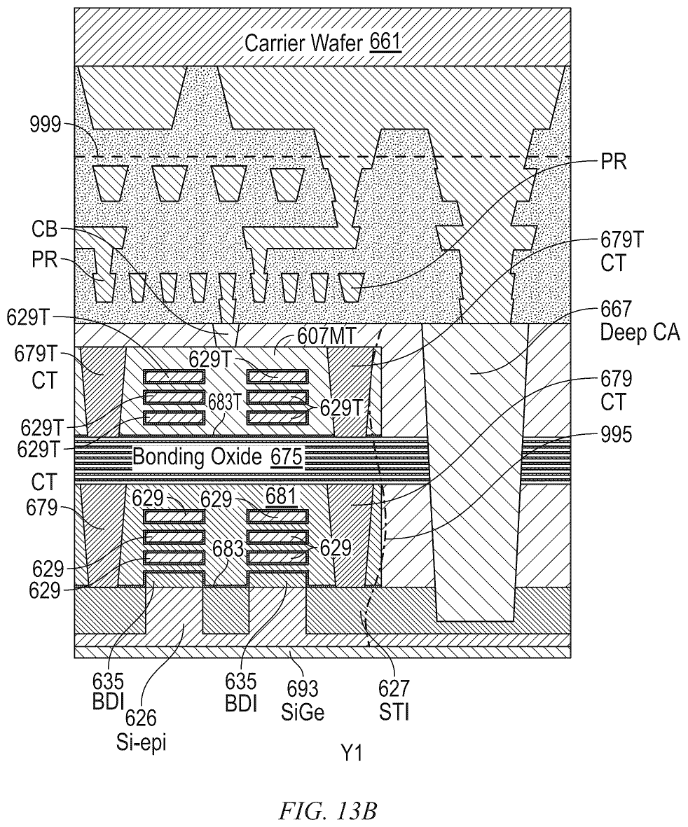

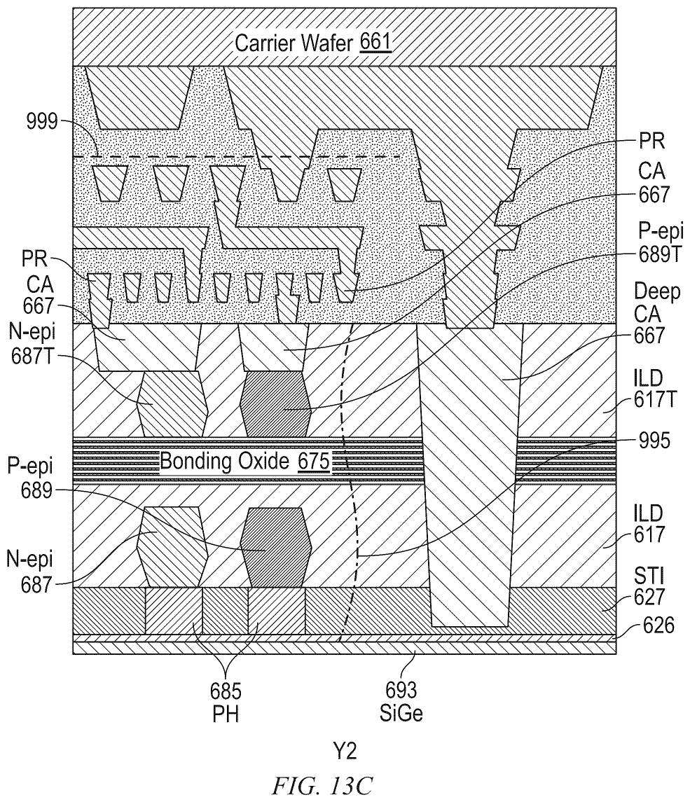

FIGS. 13A, 13B, and 13C are views of the structure of FIGS. 12A-12C, after wafer flipping and substrate removal, stopping on the SiGe 693, taken along lines X, Y1, and Y2 respectively of FIG. 3. Note that while the physical wafer has been flipped relative to Earth's gravity vector, for convenience, it is retained on the same orientation on the page as compared to FIGS. 12A-12C.

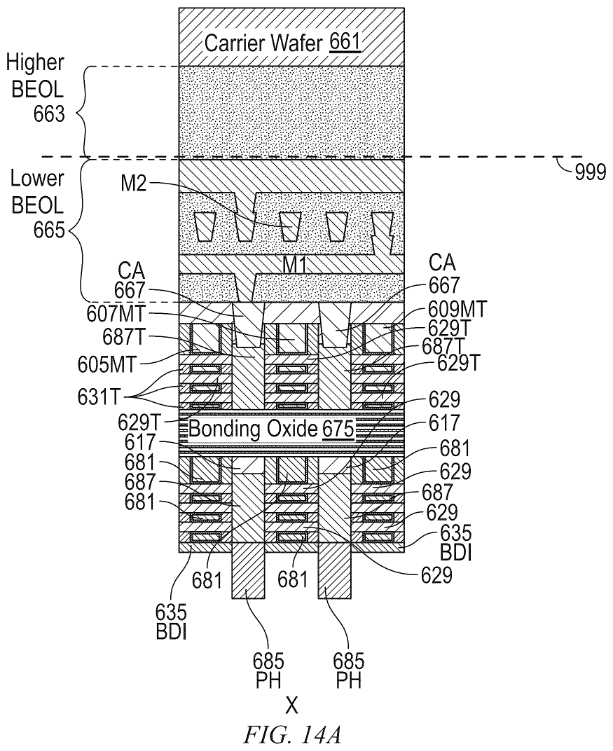

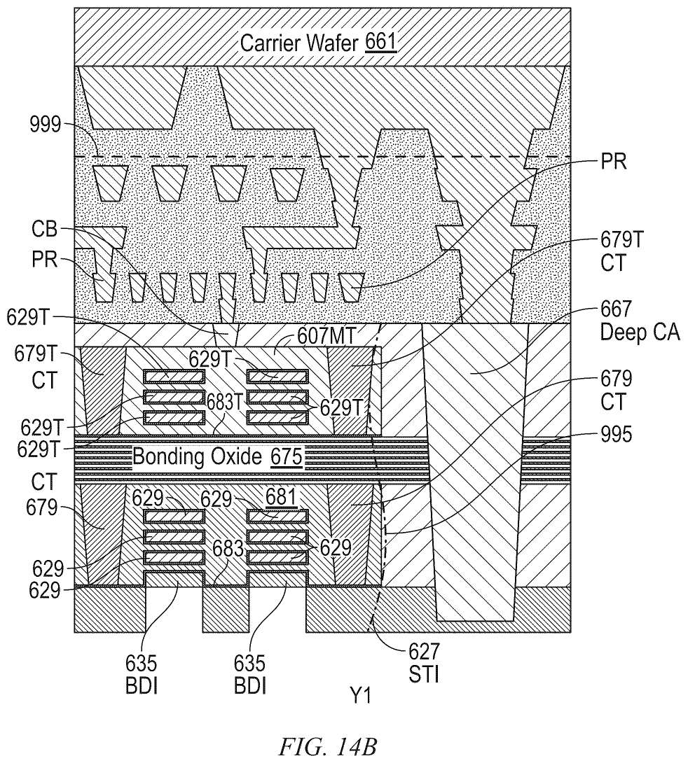

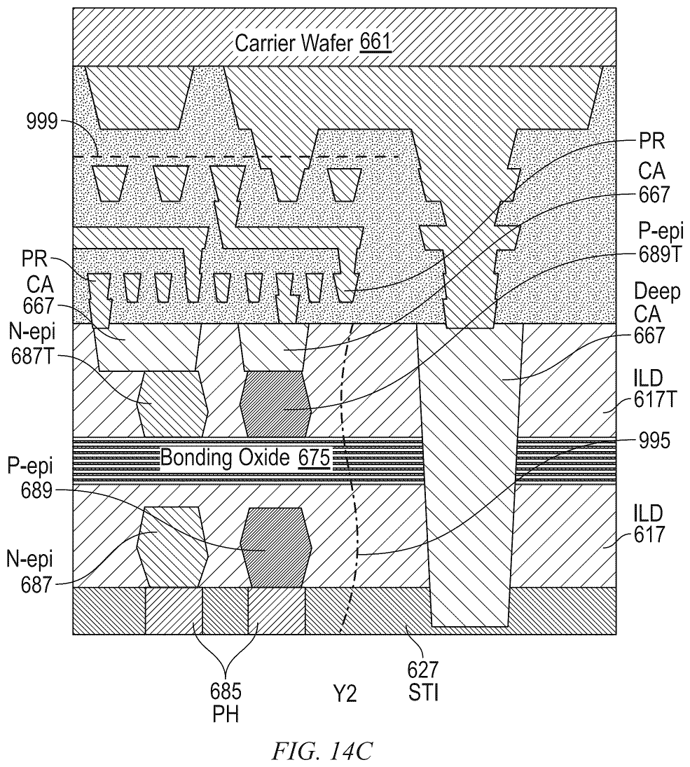

FIGS. 14A, 14B, and 14C are views of the structure of FIGS. 13A-13C, after removal of SiGe 693 and removal of epitaxially grown silicon (see additional silicon substrate 626), taken along lines X, Y1, and Y2 respectively of FIG. 3.

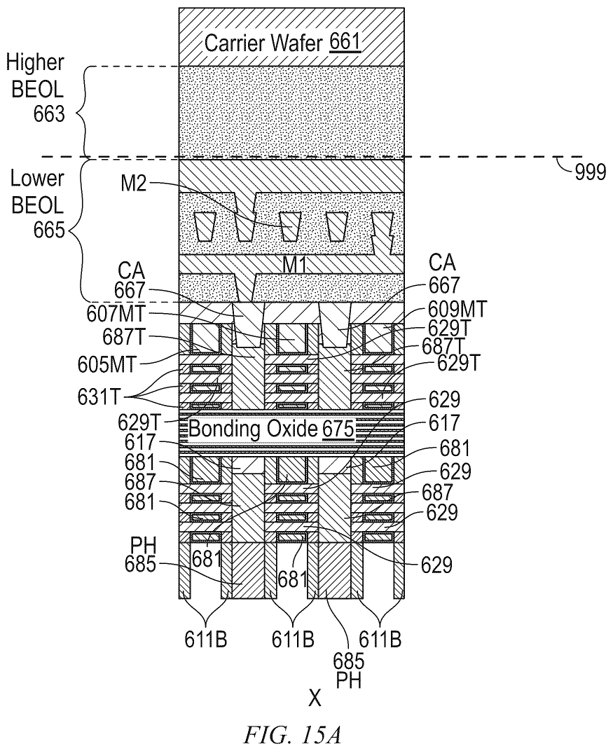

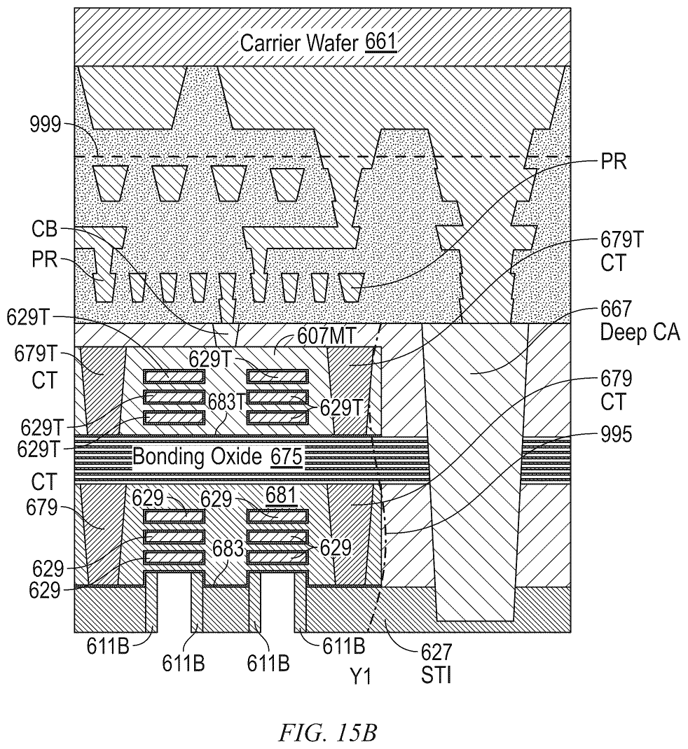

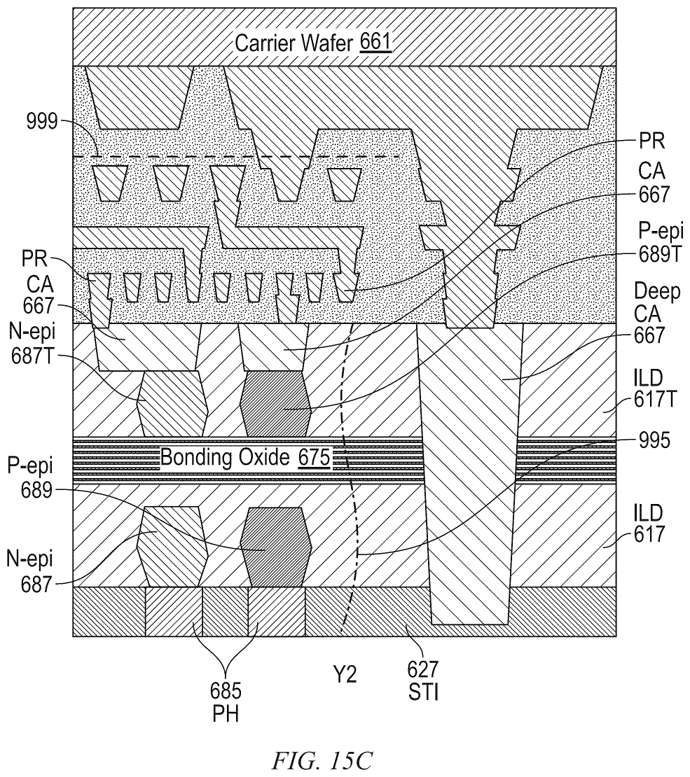

FIGS. 15A, 15B, and 15C are views of the structure of FIGS. 14A-14C, after formation of back side gate spacers 611B, taken along lines X, Y1, and Y2 respectively of FIG. 3. Note the removal of the BDI 635 stopping on the hafnium oxide HfO₂ 683.

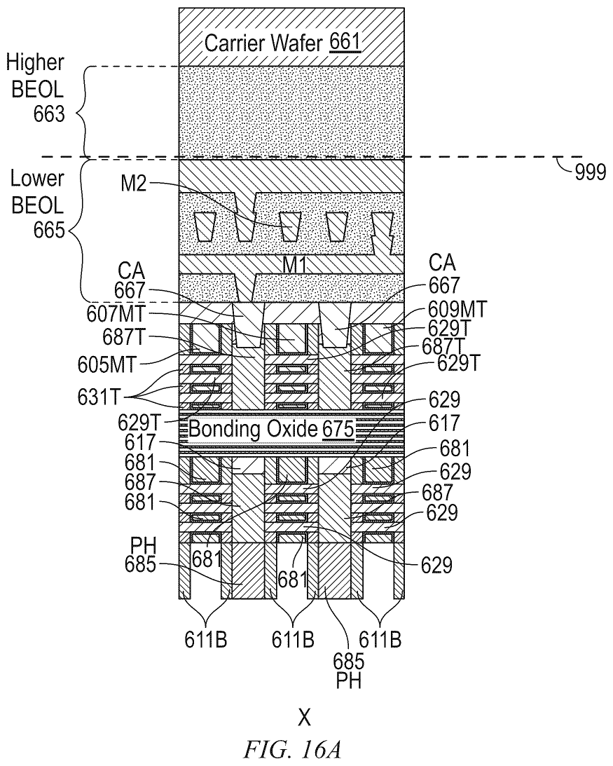

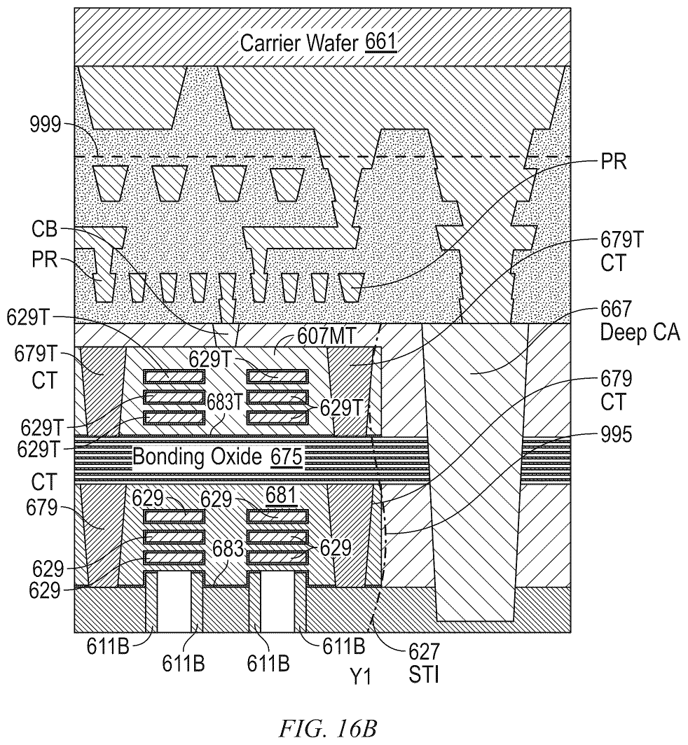

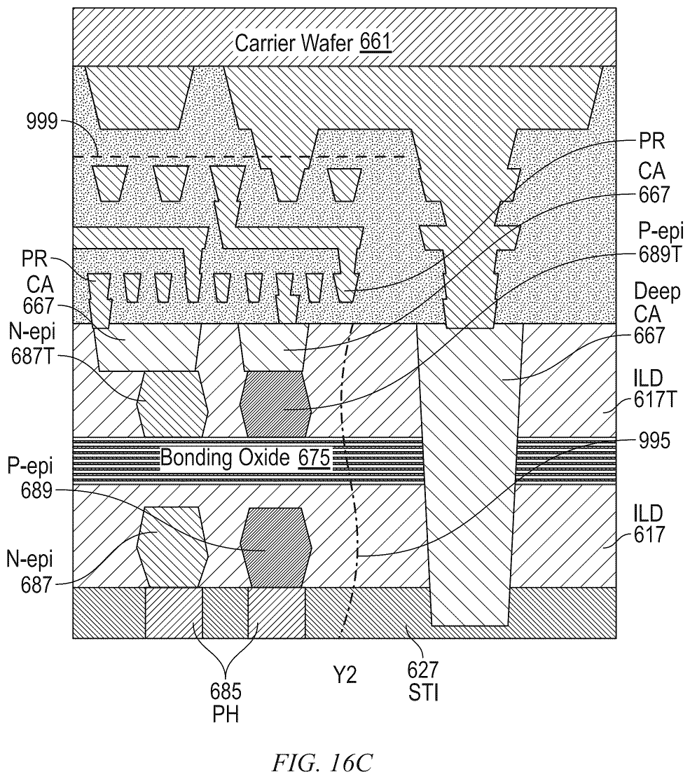

FIGS. 16A, 16B, and 16C are views of the structure of FIGS. 14A-14C, after opening exposed high-k gate dielectric material, taken along lines X, Y1, and Y2 respectively of FIG. 3 (i.e., etching through the hafnium oxide HfO₂ 683 into the amorphous silicon (a-Si) 681).

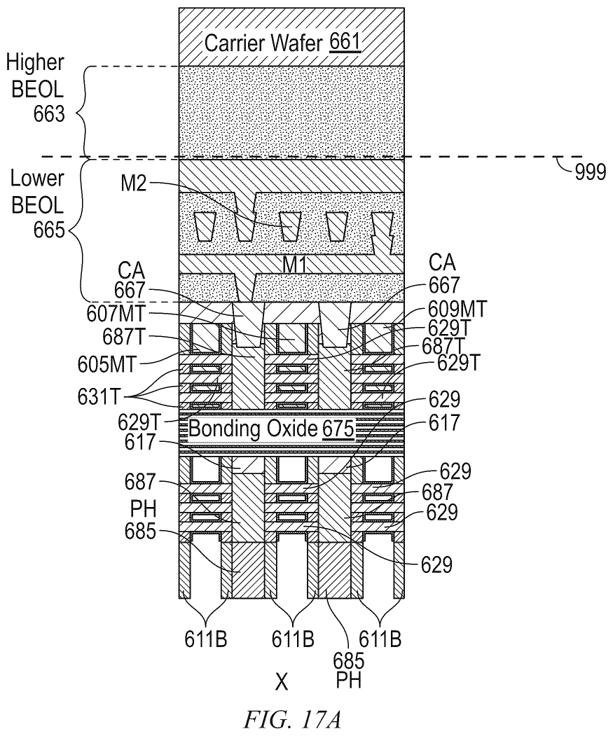

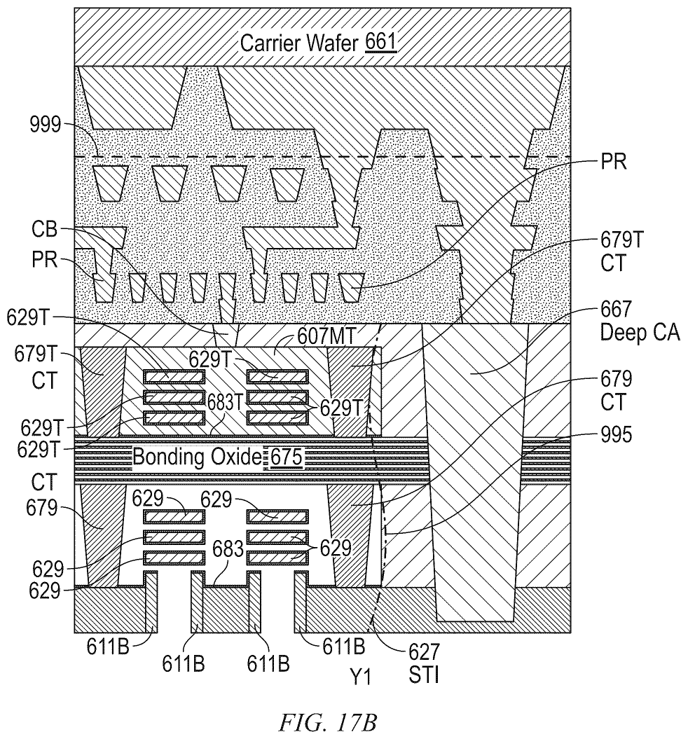

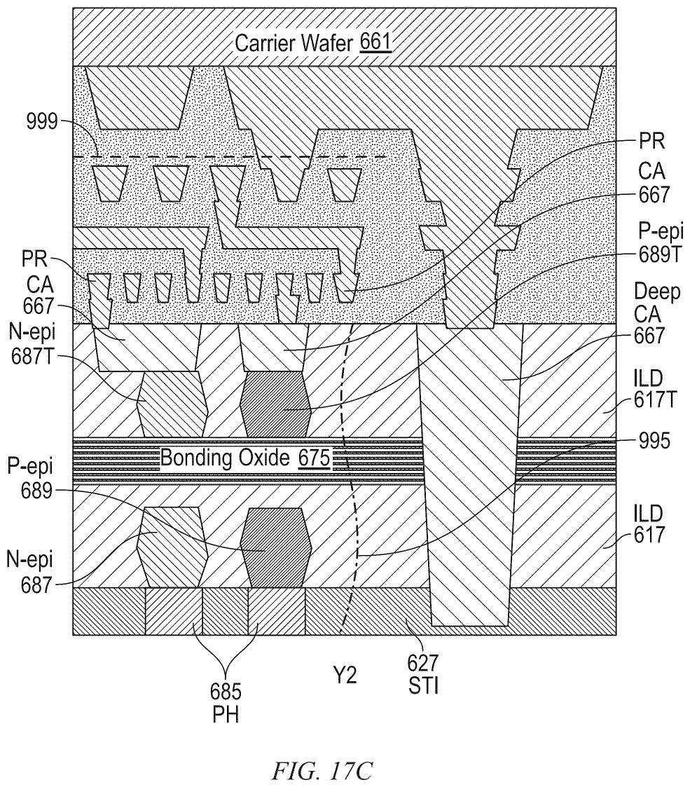

FIGS. 17A, 17B, and 17C are views of the structure of FIGS. 16A-16C, after removal of TiN/a-Si 681, taken along lines X, Y1, and Y2 respectively of FIG. 3.

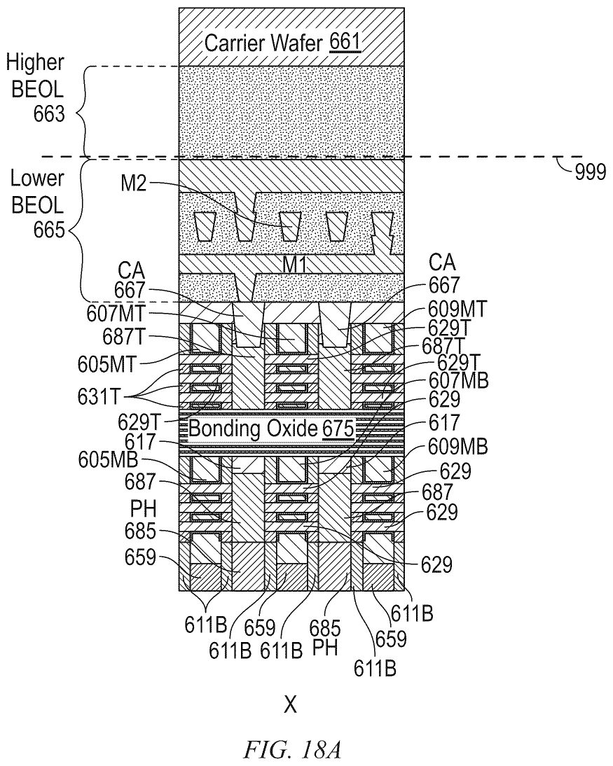

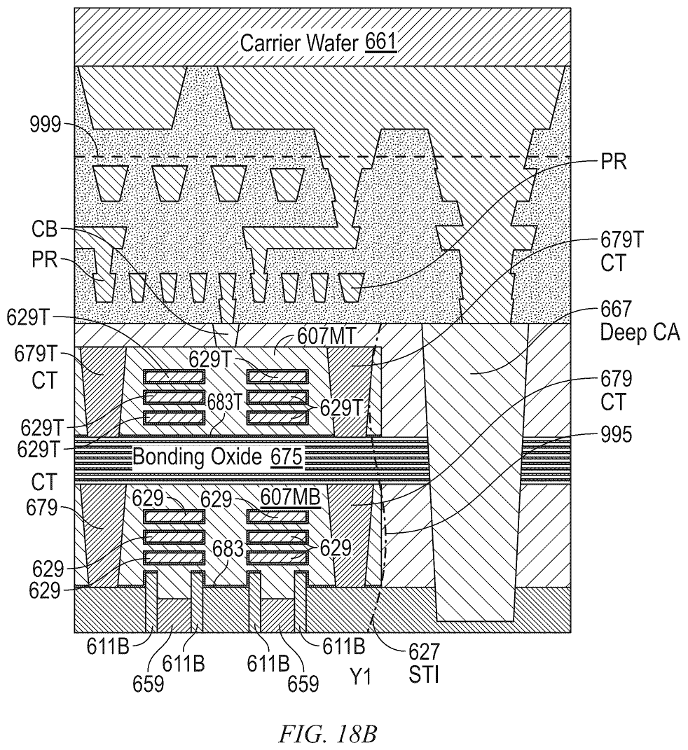

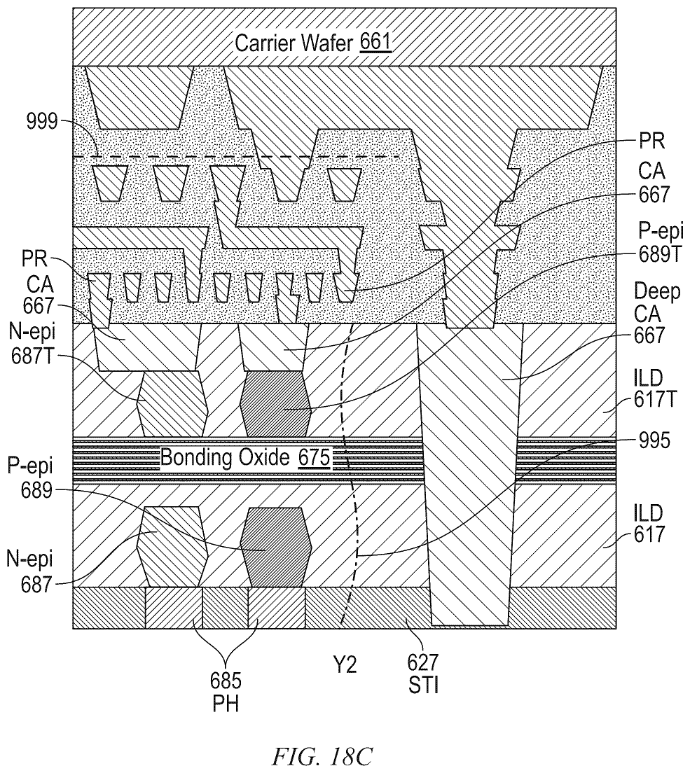

FIGS. 18A, 18B, and 18C are views of the structure of FIGS. 17A-17C, after forming replacement metal gates for the lower devices, metal gate recess, and backside gate cap formation, taken along lines X, Y1, and Y2 respectively of FIG. 3. The resultant bottom metal gates have gate metal portions numbered 605MB, 607MB, 609MB. The backside gate caps are numbered 659.

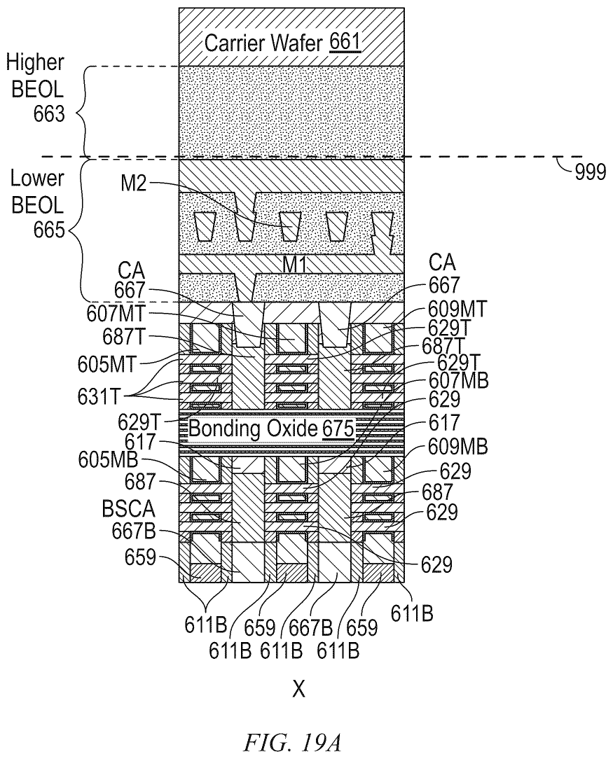

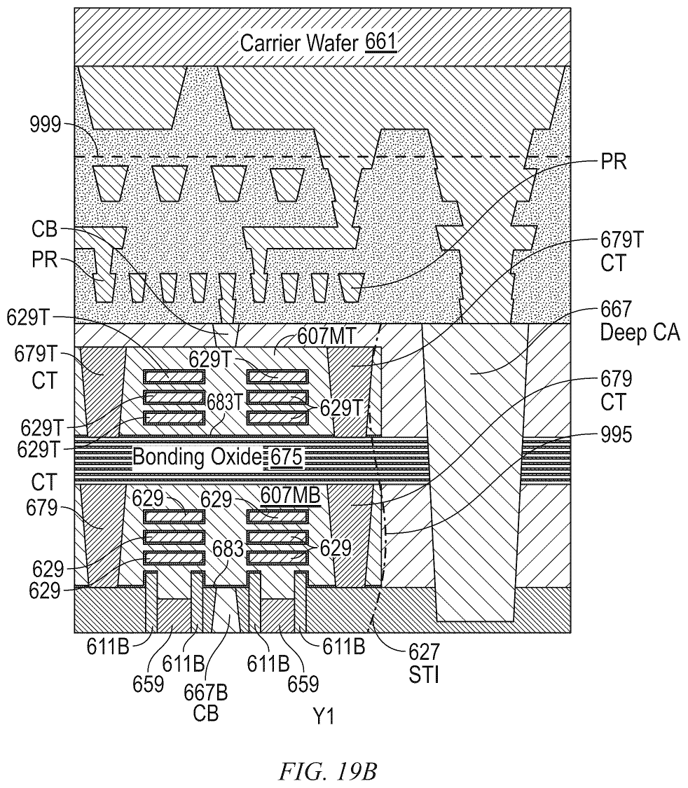

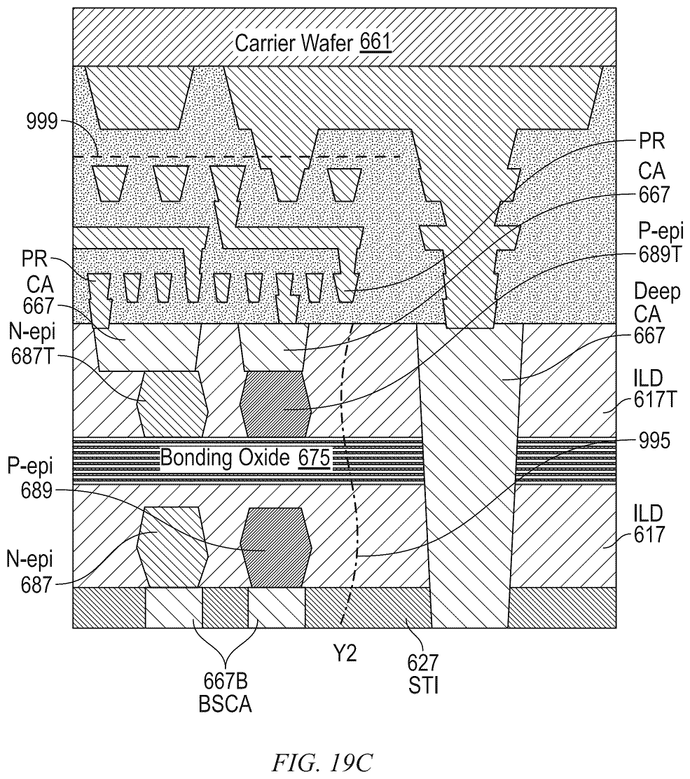

FIGS. 19A, 19B, and 19C are views of the structure of FIGS. 18A-18C, after removing placeholders 685, patterning for backside gate contacts, and forming backside contacts 667B (backside MOL processing), taken along lines X, Y1, and Y2 respectively of FIG. 3.

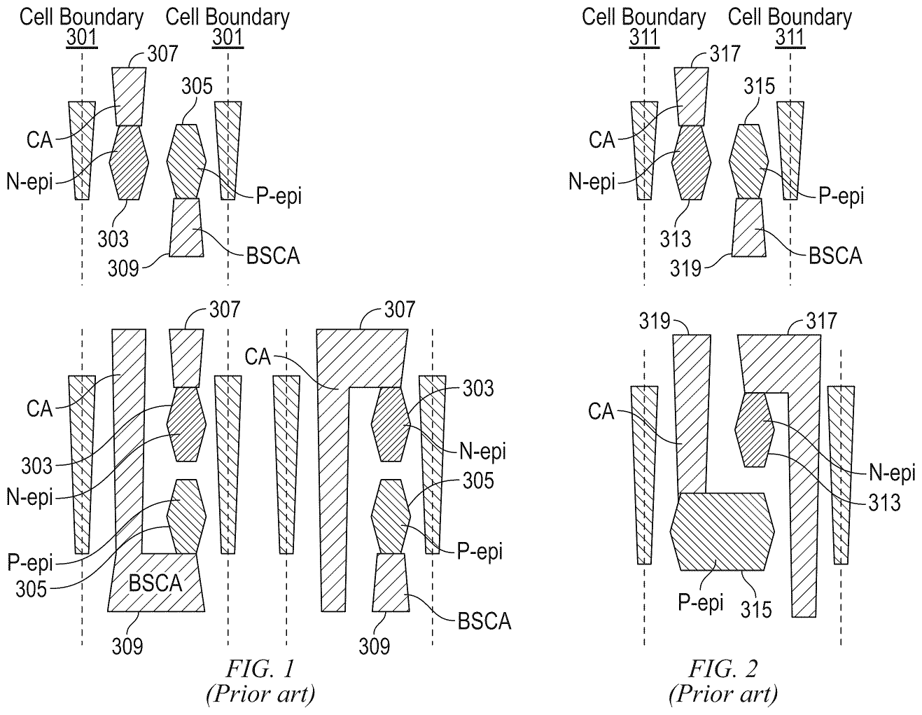

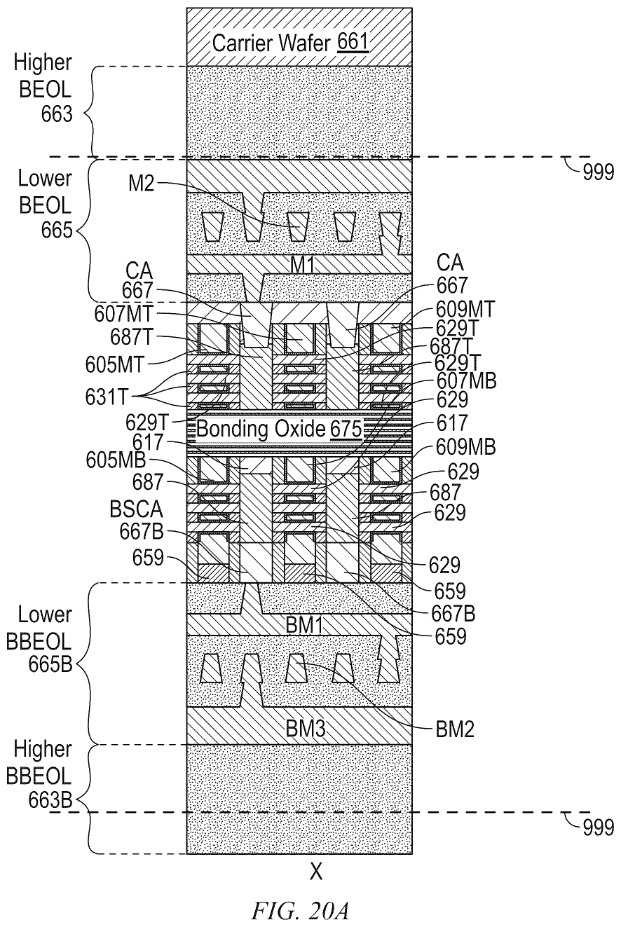

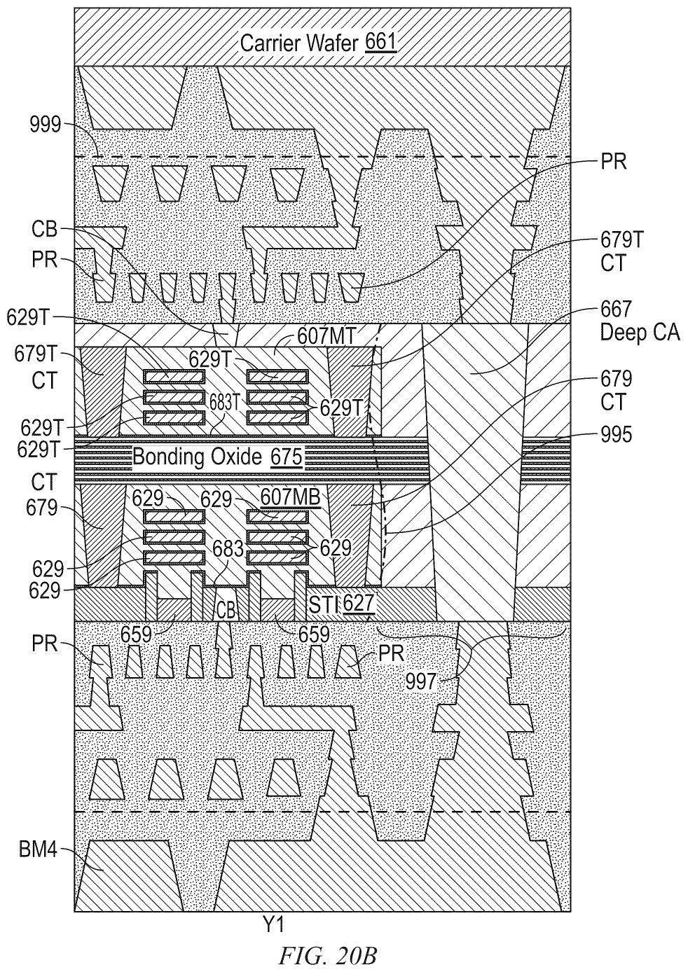

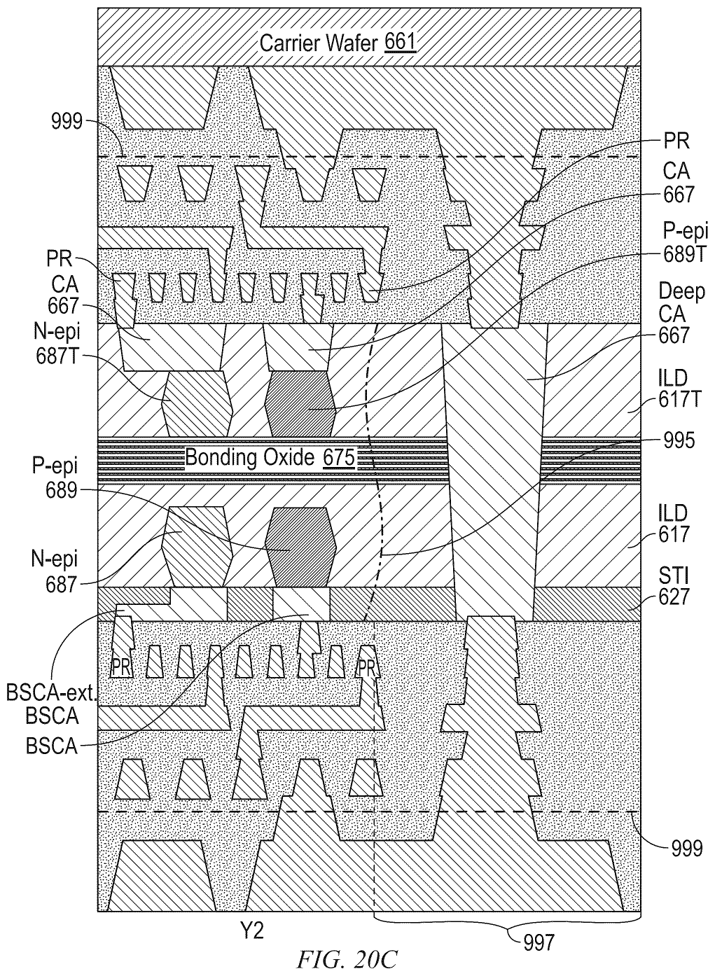

FIGS. 20A, 20B, and 20C are views of the structure of FIGS. 19A-19C, after forming backside interconnects (see discussion of 663B, 665B), taken along lines X, Y1, and Y2 respectively of FIG. 3. Note the lower backside BEOL (BBEOL) wiring 665B and higher BBEOL wiring 663B. Both the lower BBEOL wiring 665B and the higher BBEOL wiring 663B can contain additional layers of metal levels, and the drawing is for illustrative purposes and non-limiting. In the non-limiting example, there are four backside metal levels BM1, BM2, BM3, BM4 (BM1, BM2, and BM3 are seen in FIG. 20A and BM4 is seen in FIG. 20B). In the first backside metal level BM1, there is wiring for both signal routing and power delivery (power rails (PRs)). Connections are established between the top CMOS terminals (n-epi S/D 687T, p-epi S/D 689T, and gates 607MT) and bottom CMOS terminals (n-epi S/D 687, p-epi S/D 689, and gates 607MB) through the higher BEOL/BBEOL wirings and the deep via contact 667 (in this context, higher BEOL/BBEOL wiring means: higher than M2/BM2, e.g., M3/BM3, or M4/BM4, and so on). By way of clarification, as seen in FIGS. 20B and 20C, there are interconnections between contact 667 and BM4, through BM1, BM2, and BM3. The connections are established between the deep via contact 667 and the bottom CMOS terminals in BM4 which extends laterally. Given the teachings herein, the skilled artisan can form suitable BBEOL wiring including metal layers with wires and vias and with suitable insulating material in between, by adapting known techniques. Since, in one or more embodiments, the lower CMOS circuit and the higher CMOS circuit communicate with each other only at higher metal levels (e.g., higher than M2/BM2), there is no need to form top-to-bottom or bottom-to-top contacts at the transistor level as used by prior art devices described in FIGS. 1 and 2, which greatly reduces the risk of shorting between devices, reduces parasitic capacitance, and enables better cell height scaling.

The dash-dot lines 995 indicate that there are typically many other devices (not shown to avoid clutter) between the CMOS logic region (i.e., including the transistor gates, drains, sources, and nanosheet channel regions) and the peripheral region 997 (i.e., region between last device and edge of chip). The dash lines 999 indicate that there are typically many metal layers, not shown to avoid clutter, for both lower and higher BEOL.

It will accordingly be appreciated that an exemplary method of forming semiconductor device includes forming a bottom device layer with a placeholder gate stack; bonding a top device layer; forming a top device layer with an active gate stack; flipping the wafer; exposing and removing the bottom device layer placeholder gate stack; and forming the backside device layer gate stack.

In one or more embodiments, form bottom CMOS S/D epitaxy, high-k gate dielectric, and reliability anneal cappings along with a placeholder gate stack for the bottom device. Bond the top semiconductor device layer. Form top CMOS S/D epitaxy, CMOS multiple Vₜ gate stack, MOL contacts, and BEOL interconnects with both power and signals. Flip the wafer, and remove the substrate. Form self-aligned gate spacers, and remove the reliability anneal cappings on the bottom device layer after flipping. Note that in one or more embodiments, the reliability anneal capping layer is thin TiN plus a-Si; as noted above, to avoid clutter, the thin TiN and a-Si are not shown separately; element 681 represents both TiN and a-Si. Use the backside replacement gate process for the bottom CMOS device with multiple Vₜ gate stack. Form backside contacts, and backside BEOL interconnects with both power and signals. Form a connection between the higher BEOL and higher BBEOL layers at circuit peripheral regions. For example, as seen in FIGS. 20B and 20C, metal M4 and metal BM4 are connected in the circuit peripheral regions 997 using deep via contact 667.

It will be further appreciated that an exemplary structure includes a first, bottom, device layer; a second, top, device layer; a dielectric separating the top and bottom device layers; an RMG gate stack on the second, top, device layer with High-K on the dielectric separating the layers; an RMG gate stack on the first, bottom, device layer with gate metal on the dielectric separating the layers.

Optionally, the frontside BEOL is connected to the second, top, Device layer and the Backside BEOL layer is connected to the first, bottom, Device layer. There are gate dielectric cuts in the top and bottom device gates. Gate metal is located on the gate dielectric cuts in the top and bottom device gates. The substrate wafer is connected to the frontside BEOL layers. The backside gate cap isolates the gate from the backside contact or backside via. The backside gate cap is located between the STI regions, and is isolated from the STI regions by the backside gate spacer. Backside gate metal under the active channels extends lower than the top surface of the STI regions, between the backside gate spacers.

In another aspect, a semiconductor device includes an upper-level CMOS, a frontside BEOL including power rails and signal wirings, a lower-level CMOS, and a backside interconnect (BBEOL) including power rails and signal wirings. At a circuit peripheral region, higher level BBEOL and higher level BEOL are connected.

Optionally, a bonding dielectric isolates the upper-level CMOS and the lower-level CMOS.

Optionally, a handler wafer (carrier wafer) is attached to the upper surface of the BEOL of the upper-level CMOS.

Optionally, a backside gate cap is formed to isolate the gate from the backside contact or backside via.

Optionally, the backside gate cap is formed between STI regions, and is isolated from the STI regions by the backside gate spacer.

Optionally, the backside gate metal under the active channels extends lower than the top surface of the STI regions, between the backside gate spacers.

Unlike one or more prior art approaches, one or more embodiments do not require forming a local contact top to bottom. One or more embodiments provide a novel technique for forming first CMOS devices with frontside interconnects over second CMOS devices with backside interconnects. One or more embodiments employ backside contacts for the bottom device in a stacked FET arrangement. One or more embodiments form backside replacement gates and gate contacts.

In one or more embodiments, referring to FIGS. 20B and 20C, metal features in the higher BEOL wiring 663 and lower BEOL wiring 665 taper from wider at the top to narrower at the bottom, while metal features in the higher BBEOL wiring 663B and lower BBEOL wiring 665B taper from wider at the bottom to narrower at the top. Furthermore, contact 667 tapers from wider at the top to narrower at the bottom.

Given the discussion thus far, it will be appreciated that a semiconductor structure, according to an aspect of the invention, includes an upper-level complementary metal oxide semiconductor (CMOS) transistor layer having a plurality of upper-level N-type field effect transistors and a plurality of upper-level P-type field effect transistors (the n-type transistors correspond to n-epi 687T and the p-type transistors correspond to p-epi 689T). The structure further includes a frontside interconnect layer (see 663, 665) above, and interconnected with, the upper-level complementary metal oxide semiconductor (CMOS) transistor layer. The frontside interconnect layer includes both: (i) frontside power rails and (ii) frontside signal wiring. The frontside interconnect layer includes at least three frontside interconnect layer metal levels M1, M2, M3, M4,

As an aside, it is worth noting that the skilled artisan can make connections to the upper transistor layer as appropriate depending on the logical circuits implemented; for example, if a CMOS inverter is implemented, an input signal can be provided to the coupled gates, an output signal can be taken at the coupled drains, power can be provided to the source of the PFET, and the source of the NFET can be grounded.

Now continuing, the structure further includes a lower-level complementary metal oxide semiconductor (CMOS) transistor layer having a plurality of lower-level N-type field effect transistors and a plurality of lower-level P-type field effect transistors (the n-type transistors correspond to n-epi 687 and the p-type transistors correspond to p-epi 689). A backside interconnect layer 663B, 665B is below, and interconnected with, the lower-level complementary metal oxide semiconductor (CMOS) transistor layer. The backside interconnect layer includes both backside power rails and backside signal wiring. The backside interconnect layer includes at least three backside interconnect layer metal levels.

As an aside, it is worth noting that the skilled artisan can make connections to the lower transistor layer as appropriate depending on the logical circuits implemented; the inverter example provided above is equally applicable.

Now continuing, the structure further includes at least one conductive interconnection (e.g. contact) 667 between a third or higher M3, M4, . . . of the at least three frontside interconnect layer metal levels and a third or lower BM3, BM4, . . . of the at least three backside interconnect layer metal levels. The at least one conductive interconnection is located at a peripheral region 997 of the semiconductor structure.

One or more embodiments further include an intermediate dielectric region (see bonding oxide 675) separating the upper-level complementary metal oxide semiconductor (CMOS) transistor layer and the lower-level complementary metal oxide semiconductor (CMOS) transistor layer.

One or more embodiments further include a substrate wafer 661 outward of the frontside interconnect layer.

One or more embodiments further include a backside gate cap 659 interposed between high-K metal gate structures of at least some of the lower-level N-type field effect transistors and the backside interconnect layer.

In some cases, the backside gate cap isolates the gate from the backside contact or the backside via.

One or more embodiments further include a shallow trench isolation region (see STI 627 (e.g., oxide)) located between the plurality of lower-level N-type field effect transistors and the plurality of lower-level P-type field effect transistors and the backside interconnect layer.

One or more embodiments further include back side gate spacers 611B isolating the backside gate cap from the shallow trench isolation region.

As best seen in FIG. 20B, in some cases, the high-K metal gate structures of the at least some of the lower-level N-type field effect transistors include a region between the back side gate spacers that extends inward below an outer surface of the shallow trench isolation region, inward of at least one channel region of the at least some of the lower-level N-type field effect transistors.

In some cases, the plurality of upper-level N-type field effect transistors and the plurality of upper-level P-type field effect transistors each have upper field effect transistor high-K metal gate structures defined by upper gate dielectric cuts 679T and the plurality of lower-level N-type field effect transistors and the plurality of lower-level P-type field effect transistors each have lower field effect transistor high-K metal gate structures defined by lower gate dielectric cuts 679.

In some such cases, metal portions of the upper field effect transistor high-K metal gate structures contact the upper gate dielectric cuts and metal potions of the lower field effect transistor high-K metal gate structures contact the lower gate dielectric cuts.

In some such cases, high-K dielectric portions of the upper field effect transistor high-K metal gate structures contact the intermediate dielectric region and the metal potions of the lower field effect transistor high-K metal gate structures contact the intermediate dielectric region.

In one or more embodiments, the frontside power rails and the frontside signal wiring are included in at least a first (i.e., closest to the devices) of the at least three frontside interconnect layer metal levels; and the backside power rails and the backside signal wiring are included in at least a first (i.e., closest to the devices) of the at least three backside interconnect layer metal levels.

In at least some such embodiments, the at least one conductive interconnection includes a deep via contact 667.

In at least some such embodiments, at least one terminal (e.g., gate, drain, or source) of the upper-level complementary metal oxide semiconductor (CMOS) transistor layer is electrically interconnected to at least one terminal (e.g., gate, drain, or source) of the lower-level complementary metal oxide semiconductor (CMOS) transistor layer through the deep via contact, the third or higher of the at least three frontside interconnect layer metal levels and the third or lower of the at least three backside interconnect layer metal levels.

In one or more embodiments, at least one transistor of one of N-type and P-type, selected from the plurality of upper-level N-type field effect transistors and the plurality of upper-level P-type field effect transistors, has a different threshold voltage than at least one other transistor of the one of N-type and P-type, selected from the plurality of upper-level N-type field effect transistors and the plurality of upper-level P-type field effect transistors.

In one or more embodiments, at least one transistor of one of N-type and P-type, selected from the plurality of lower-level N-type field effect transistors and the plurality of lower-level P-type field effect transistors, has a different threshold voltage than at least one other transistor of the one of N-type and P-type, selected from the plurality of lower-level N-type field effect transistors and the plurality of lower-level P-type field effect transistors.

Generally, the upper layer transistors and/or the lower layer transistors can have multiple threshold voltages.

As noted, in the lower-level complementary metal oxide semiconductor (CMOS) transistor layer having the plurality of lower-level N-type field effect transistors and the plurality of lower-level P-type field effect transistors, the n-type transistors correspond to n-epi 687 and the p-type transistors correspond to p-epi 689. Thus, each lower n-type field effect transistor will include: first and second lower n-type field effect transistor source-drain regions 687; at least one lower n-type field effect transistor channel region (see nanosheet channels 629) interconnecting the first and second lower n-type field effect transistor source-drain regions; and a lower n-type field effect transistor high-K metal gate structure with HfO₂ 683 and with 605MB, 607MB, 609MB, at least partially surrounding the at least one lower n-type field effect transistor channel region. The lower n-type field effect transistor high-K metal gate structure includes a lower field effect transistor gate high-K dielectric portion (see HfO₂ 683) and a lower field effect transistor gate metal portion 605MB, 607MB, 609MB. Each lower p-type field effect transistor will be similar but the first and second lower p-type field effect transistor source-drain regions are numbered 689.

Furthermore, as noted, in the upper-level complementary metal oxide semiconductor (CMOS) transistor layer having the plurality of upper-level N-type field effect transistors and the plurality of upper-level P-type field effect transistors, the n-type transistors correspond to n-epi 687T and the p-type transistors correspond to p-epi 689T. Thus, each upper n-type field effect transistor will include: first and second upper n-type field effect transistor source-drain regions 687T; at least one upper n-type field effect transistor channel region (see top nanosheet channels 629T) interconnecting the first and second upper n-type field effect transistor source-drain regions; and an upper n-type field effect transistor high-K metal gate structure (see top high-k gate dielectric 683T) and 605MT, 607MT, 609MT at least partially surrounding the at least one upper n-type field effect transistor channel region. The upper n-type field effect transistor high-K metal gate structure includes an upper field effect transistor gate high-K dielectric portion (see top high-k gate dielectric 683T) and an upper field effect transistor gate metal portion 605MT, 607MT, 609MT. Each upper p-type field effect transistor will be similar but the first and second upper p-type field effect transistor source-drain regions are numbered 689T.

In another aspect, an exemplary method of forming a semiconductor structure includes providing a starting structure, such as is seen in FIG. 6A-6C, including: a silicon substrate 695; an etch stop liner (e.g., SiGe 693) above the silicon substrate; an additional silicon substrate 626 above the etch stop liner, the additional silicon substrate having a plurality of shallow trench isolation regions (see STI 627 (e.g., oxide)) formed therein; bottom dielectric isolation (BDI) 635 above the additional silicon substrate; and bottom dummy gate stacks above the bottom dielectric isolation (BDI). The bottom dummy gate stacks are separated by bottom source-drain regions 687, 689 and bottom gate cuts 679. The bottom dummy gate stacks surround bottom channel regions (see nanosheet channels 629). Also included are bottom interlayer dielectric (ILD 617) separating the bottom source-drain regions and placeholders 685 in the additional silicon substrate, inward of the bottom source-drain regions.

A further step includes bonding, onto an outer surface of the starting structure, using a bonding layer (see bonding oxide 675), a top stack 677 including alternating channel and sacrificial SiGe regions and an outer silicon substrate 673, to obtain a first intermediate structure, as seen in FIGS. 7A-7C.

A still further step includes processing the first intermediate structure to obtain a second intermediate structure. Referring to FIGS. 12A-12C, the second intermediate structure includes the starting structure; the bonding layer; and top high-K metal gate stacks above the bonding layer opposite the bottom dummy gate stacks. The top high-K metal gate stacks are separated by top source-drain regions 687T, 689T and top gate cuts 679T. The top high-K metal gate stacks surround top channel regions (see top nanosheet channels 629T) formed from the alternating channel regions of the top stack. The second intermediate structure further includes top interlayer dielectric (ILD) 617T separating the top source-drain regions; top source, drain, and gate contacts; and a frontside interconnect layer outward of the top high-K metal gate stacks, electrically interconnected with the top source, drain, and gate contacts and including both top power and top signal wiring. The frontside interconnect layer includes both frontside power rails and frontside signal wiring. The frontside interconnect layer includes at least three frontside interconnect layer metal levels. A carrier wafer is outward of the frontside interconnect layer. Contacts 667 are at peripheral regions of the semiconductor structure and are electrically interconnected to a third or higher M3, M4, . . . of the at least three frontside interconnect layer metal levels and pass through the bonding layer, the bottom interlayer dielectric and the top interlayer dielectric.

Further steps include flipping the second intermediate structure and etching the silicon substrate down to the etch stop liner (see FIGS. 13A-13C); carrying out high-K metal gate replacement on the bottom dummy gate stacks (e.g., remove dummy gate to obtain structure of FIGS. 17A-17C, then carry out HKMG process per FIG. 18A-18C).

An even further step includes forming bottom source, drain, and gate contacts 667B, and a backside interconnect layer 663B, 665B inward of the bottom replacement gates, electrically interconnected with the bottom source, drain, and gate contacts and including both bottom power and bottom signal wiring. The backside interconnect layer includes both backside power rails and backside signal wiring. The backside interconnect layer includes at least three backside interconnect layer metal levels. The contacts 667 at the peripheral regions are electrically interconnected to a third or lower BM3, BM4, . . . of the at least three backside interconnect layer metal levels, and at least some of the placeholders are replaced by at least some of the bottom source, drain, and gate contacts. The placeholders can, generally, be replaced by source, drain, and/or gate contacts.

One or more embodiments further include, prior to forming the bottom source, drain, and gate contacts, forming backside gate caps inward of portions of high-K metal gate structures formed during the high-K metal gate replacement on the bottom dummy gate stacks, inward of the bottom channel regions.

Given the teachings herein, for any elements for which example materials are not set forth, the skilled artisan can select appropriate materials, and for any fabrication steps for which specific exemplary processes have not been set forth, the skilled artisan can select appropriate known processes. Exemplary known processes, in no particular order, include, for example, preparation (deposition/patterning) of nanosheet stacks with sacrificial SiGe regions, etch-back of sacrificial SiGe, formation of shallow trench isolation (STI), dummy gates including gate spacers, inner spacers, and BDI, dummy gate open, dummy gate removal, channel release, HKMG stack deposition, backside gate cap and trench metal contact formation, and with lithography, masks, and patterning, generally. The skilled artisan will be familiar with the “dummy gate” process for forming HKMGs. More generally, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term.

Bulk silicon is a non-limiting example of a suitable substrate material, other materials are also possible.

Note that for any materials and processes not specifically called out, standard materials and processes for fabrication of GAA nanosheet transistors can be adapted by the skilled artisan, given the teaching herein.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching.” For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

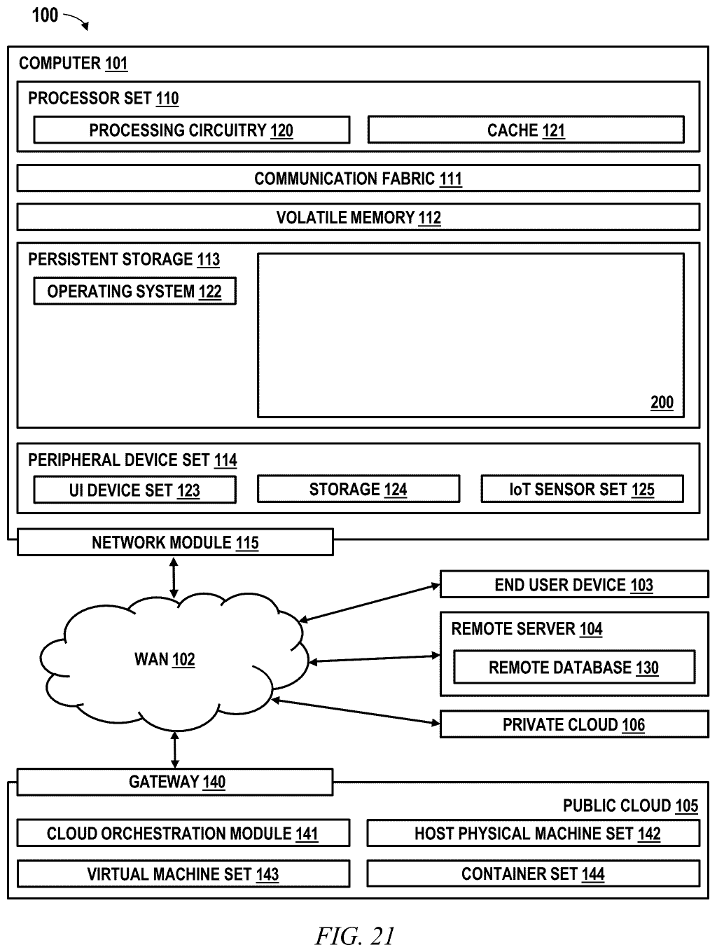

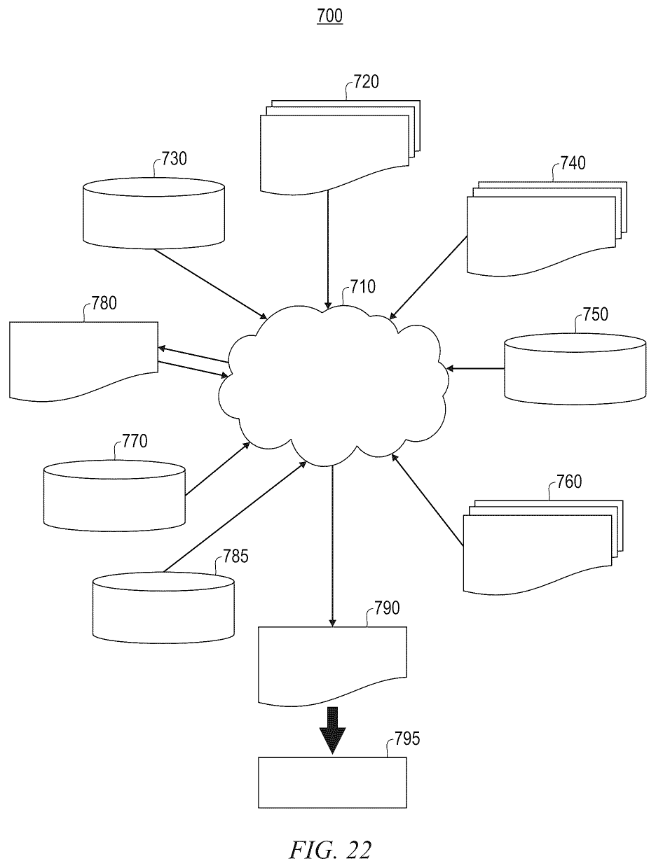

Reference should now be had to FIG. 21, which depicts a computing environment according to an embodiment of the present invention (e.g., for implementing a design process such as that of FIG. 22)

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system (see block 200) for semiconductor design and/or control of semiconductor fabrication (see FIG. 22). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 21. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 22 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 22 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
an upper-level complementary metal oxide semiconductor (CMOS) transistor layer having a plurality of upper-level N-type field effect transistors and a plurality of upper-level P-type field effect transistors;
a frontside interconnect layer above, and interconnected with, the upper-level complementary metal oxide semiconductor (CMOS) transistor layer, the frontside interconnect layer including frontside power rails and frontside signal wiring, the frontside interconnect layer including at least three frontside interconnect layer metal levels;
a lower-level complementary metal oxide semiconductor (CMOS) transistor layer having a plurality of lower-level N-type field effect transistors and a plurality of lower-level P-type field effect transistors;
a backside interconnect layer below, and interconnected with, the lower-level complementary metal oxide semiconductor (CMOS) transistor layer, the backside interconnect layer including backside power rails and backside signal wiring, the backside interconnect layer including at least three backside interconnect layer metal levels; and
at least one conductive interconnection between a third or higher of the at least three frontside interconnect layer metal levels and a third or lower of the at least three backside interconnect layer metal levels, the at least one conductive interconnection being located at a peripheral region of the semiconductor structure.

2. The semiconductor structure of claim 1, further comprising an intermediate dielectric region separating the upper-level complementary metal oxide semiconductor (CMOS) transistor layer and the lower-level complementary metal oxide semiconductor (CMOS) transistor layer.

3. The semiconductor structure of claim 2, further comprising a substrate wafer outward of the frontside interconnect layer.

4. The semiconductor structure of claim 2, further comprising a backside gate cap interposed between high-K metal gate structures of at least some of the lower-level N-type field effect transistors and the backside interconnect layer.

5. The semiconductor structure of claim 4, further comprising a shallow trench isolation region located between the plurality of lower-level N-type field effect transistors and the plurality of lower-level P-type field effect transistors and the backside interconnect layer.

6. The semiconductor structure of claim 5, further comprising back side gate spacers isolating the backside gate cap from the shallow trench isolation region.

7. The semiconductor structure of claim 6, wherein the high-K metal gate structures of the at least some of the lower-level N-type field effect transistors include a region between the back side gate spacers that extends inward below an outer surface of the shallow trench isolation region, inward of at least one channel region of the at least some of the lower-level N-type field effect transistors.

8. The semiconductor structure of claim 1, wherein the plurality of upper-level N-type field effect transistors and the plurality of upper-level P-type field effect transistors each have upper field effect transistor high-K metal gate structures defined by upper gate dielectric cuts and the plurality of lower-level N-type field effect transistors and the plurality of lower-level P-type field effect transistors each have lower field effect transistor high-K metal gate structures defined by lower gate dielectric cuts.

9. The semiconductor structure of claim 8, wherein metal portions of the upper field effect transistor high-K metal gate structures contact the upper gate dielectric cuts and metal potions of the lower field effect transistor high-K metal gate structures contact the lower gate dielectric cuts.

10. The semiconductor structure of claim 8, wherein high-K dielectric portions of the upper field effect transistor high-K metal gate structures contact the intermediate dielectric region and the metal potions of the lower field effect transistor high-K metal gate structures contact the intermediate dielectric region.

11. The semiconductor structure of claim 1, wherein:
the frontside power rails and the frontside signal wiring are included in at least a first of the at least three frontside interconnect layer metal levels; and
the backside power rails and the backside signal wiring are included in at least a first of the at least three backside interconnect layer metal levels.

12. The semiconductor structure of claim 11, wherein the at least one conductive interconnection comprises a deep via contact.

13. The semiconductor structure of claim 12, wherein at least one terminal of the upper-level complementary metal oxide semiconductor (CMOS) transistor layer is electrically interconnected to at least one terminal of the lower-level complementary metal oxide semiconductor (CMOS) transistor layer through the deep via contact, the third or higher of the at least three frontside interconnect layer metal levels and the third or lower of the at least three backside interconnect layer metal levels.

14. The semiconductor structure of claim 1, wherein at least one transistor of one of N-type and P-type, selected from the plurality of upper-level N-type field effect transistors and the plurality of upper-level P-type field effect transistors, has a different threshold voltage than at least one other transistor of the one of N-type and P-type, selected from the plurality of upper-level N-type field effect transistors and the plurality of upper-level P-type field effect transistors.

15. The semiconductor structure of claim 1, wherein at least one transistor of one of N-type and P-type, selected from the plurality of lower-level N-type field effect transistors and the plurality of lower-level P-type field effect transistors, has a different threshold voltage than at least one other transistor of the one of N-type and P-type, selected from the plurality of lower-level N-type field effect transistors and the plurality of lower-level P-type field effect transistors.

16. A method of forming a semiconductor structure, comprising:
providing a starting structure comprising:
a silicon substrate;
an etch stop liner above the silicon substrate;
an additional silicon substrate above the etch stop liner, the additional silicon substrate having a plurality of shallow trench isolation regions formed therein;
bottom dielectric isolation (BDI) above the additional silicon substrate; and
bottom dummy gate stacks above the bottom dielectric isolation (BDI), the bottom dummy gate stacks being separated by bottom source-drain regions and bottom gate cuts, the bottom dummy gate stacks surrounding bottom channel regions; and
bottom interlayer dielectric separating the bottom source-drain regions;
placeholders in the additional silicon substrate, inward of the bottom source-drain regions;
bonding, onto an outer surface of the starting structure, using a bonding layer, a top stack including alternating channel and sacrificial SiGe regions and an outer silicon substrate, to obtain a first intermediate structure;
processing the first intermediate structure to obtain a second intermediate structure comprising:
the starting structure;
the bonding layer;
top high-K metal gate stacks above the bonding layer opposite the bottom dummy gate stacks, the top high-K metal gate stacks being separated by top source-drain regions and top gate cuts, the top high-K metal gate stacks surrounding top channel regions formed from the alternating channel regions of the top stack;
top interlayer dielectric separating the top source-drain regions;
top source, drain, and gate contacts;
a frontside interconnect layer outward of the top high-K metal gate stacks, electrically interconnected with the top source, drain, and gate contacts and including top power and top signal wiring, the frontside interconnect layer including frontside power rails and frontside signal wiring, the frontside interconnect layer including at least three frontside interconnect layer metal levels;
a carrier wafer outward of the frontside interconnect layer; and
contacts at peripheral regions of the semiconductor structure and electrically interconnected to a third or higher of the at least three frontside interconnect layer metal levels and passing through the bonding layer, the bottom interlayer dielectric and the top interlayer dielectric;
flipping the second intermediate structure and etching the silicon substrate down to the etch stop liner;
carrying out high-K metal gate replacement on the bottom dummy gate stacks; and
forming bottom source, drain, and gate contacts, and a backside interconnect layer inward of the bottom replacement gates, electrically interconnected with the bottom source, drain, and gate contacts and including bottom power wiring and bottom signal wiring, the backside interconnect layer including backside power rails and backside signal wiring, the backside interconnect layer including at least three backside interconnect layer metal levels, the contacts at the peripheral regions being electrically interconnected to a third or lower of the at least three backside interconnect layer metal levels, at least some of the placeholders being replaced by at least some of the bottom source, drain, and gate contacts.

17. The method of claim 16, further comprising, prior to forming the bottom source, drain, and gate contacts, forming backside gate caps inward of portions of high-K metal gate structures formed during the high-K metal gate replacement on the bottom dummy gate stacks, inward of the bottom channel regions.

18. A hardware description language (HDL) design structure encoded on a machine-readable data storage medium, the HDL design structure comprising elements that when processed in a computer-aided design system generates a machine-executable representation of a semiconductor structure, wherein the HDL design structure comprises:
an upper-level complementary metal oxide semiconductor (CMOS) transistor layer having a plurality of upper-level N-type field effect transistors and a plurality of upper-level P-type field effect transistors;
a frontside interconnect layer above, and interconnected with, the upper-level complementary metal oxide semiconductor (CMOS) transistor layer, the frontside interconnect layer including frontside power rails and frontside signal wiring, the frontside interconnect layer including at least three frontside interconnect layer metal levels;
a lower-level complementary metal oxide semiconductor (CMOS) transistor layer having a plurality of lower-level N-type field effect transistors and a plurality of lower-level P-type field effect transistors;
a backside interconnect layer below, and interconnected with, the lower-level complementary metal oxide semiconductor (CMOS) transistor layer, the backside interconnect layer including backside power rails and backside signal wiring, the backside interconnect layer including at least three backside interconnect layer metal levels; and
at least one conductive interconnection between a third or higher of the at least three frontside interconnect layer metal levels and a third or lower of the at least three backside interconnect layer metal levels, the at least one conductive interconnection being located at a peripheral region of the semiconductor structure.

19. The hardware description language (HDL) design structure of claim 18, wherein the HDL design structure further comprises an intermediate dielectric region separating the upper-level complementary metal oxide semiconductor (CMOS) transistor layer and the lower-level complementary metal oxide semiconductor (CMOS) transistor layer.

20. The hardware description language (HDL) design structure of claim 19, wherein the HDL design structure further comprises a substrate wafer outward of the frontside interconnect layer.
